(19) United States
(12) Patent Application Publication
(10) Pub. No.: US 2007/0190235 A1
(43) Pub. Date: Aug. 16, 2007

(54) FILM FORMING APPARATUS, FILM FORMING METHOD, AND MANUFACTURING METHOD OF LIGHT EMITTING ELEMENT

(75) Inventors: Shunpei YAMAZAKI, Tokyo (JP); Junichiro SAKATA, Atsugi (JP); Yoshiaki YAMAMOTO, Atsugi (JP); Miki KATAYAMA, Atsugi (JP); Kohei YOKOYAMA, Ayase (JP); Rie MATSUBARA, Isehara (JP); Takahiro KAWAKAMI, Isehara (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/671,225

(22) Filed: Feb. 5, 2007

(30) Foreign Application Priority Data
Feb. 10, 2006 (JP) 2006-034510
Feb. 10, 2006 (JP) 2006-034514

(51) Int. Cl. B05D 5/12; B05D 5/06; C23C 8/00; C23C 16/00

(52) U.S. Cl. 427/64; 427/585; 118/726; 118/723 VE

(57) ABSTRACT

An object of the present invention is to provide a film forming method for forming a film with reduced defect and to provide a film forming method for forming a film with a uniform quality. In addition, another object is to provide a manufacturing method of a light emitting element which can be driven with low voltage. Further, another object is to provide a manufacturing method of a light emitting element with high light emission efficiency. A film with reduced defect and a uniform quality can be formed by fixing a substrate to a substrate holding unit so that at least a part of a surface of the substrate is exposed, evaporating a vapor deposition material from an evaporation source filled with the vapor deposition material, irradiating the vapor deposition material which is evaporated with a laser beam, and depositing the vapor deposition material on the surface of the substrate.

### BACKGROUND OF THE INVENTION

1. Field of the Invention

The present invention relates to a film forming method and a film forming apparatus of a thin film. In addition, the present invention relates to a manufacturing method of a light emitting element.

2. Description of the Related Art

Recently, display devices included in a television, a mobile phone, a digital camera, and the like are required to be flat and thin. As a display device which meets such a requirement, a display device using a self-light emitting element has drawn attention. One of self-light emitting elements is a light emitting element utilizing electroluminescence (Electro Luminescence), in which a light emitting material is interposed between a pair of electrodes, and light emission from the light emitting material can be obtained by applying voltage.

Such a self-light emitting element has advantages over a liquid crystal display in that visibility of a pixel is high, backlight is not necessary, and the like; therefore, the self-light emitting element is considered suitable for a flat panel display element. In addition, another great advantage of such a light emitting element is that it can be manufactured to be thin and light weight. Further, its response speed is remarkably high.

Such a self-light emitting element can be formed to have a film-shape; therefore, by forming an element having a large area, a plane light emission can be obtained easily. This is characteristic is hard to be obtained by a point light source typified by a filament lamp and an LED or a linear light source typified by a fluorescent light. Therefore, the self-light emitting element also has a high utility value as a plane light source that can be applied to lighting and the like.

A light emitting element utilizing electroluminescence is classified according to whether a light emitting material thereof is an organic compound or an inorganic compound. In general, the former is called an organic EL element and the latter is called an inorganic EL element.

An inorganic EL element is classified into a dispersed inorganic EL element and a thin film inorganic EL element according to its element structure. The difference is that the former has a light emitting layer in which particles of a light emitting material are dispersed in a binder, and the latter has a light emitting layer formed of a thin film of a phosphor. However, they have a mechanism in common and light emission can be obtained by collision excitation of electrons accelerated by a high electric field, with a base material or light emission center. Accordingly, to obtain light emission with a general inorganic EL element, a high electric field is required and application of voltage of several hundreds volts to a light emitting element is required. For example, an inorganic EL element which emits blue light with high luminance required for full color display is developed recently, which needs driving voltage of 100 to 200 V (for example, see non-patent document 1: Japanese Journal of Applied Physics, 1999, Vol. 38, p. L1291). Therefore, an inorganic EL element has high power consumption and is difficult to be applied to a small or medium sized display, such as a display in a mobile phone.

As a method for manufacturing an inorganic EL element, a resistance heating vapor deposition method, an electron beam vapor deposition method (an EB vapor deposition method), or the like can be given. In the case of manufacturing an inorganic EL element by these methods, a material is once evaporated. When the material is being evaporated, a composition thereof changes. The material is recombined when a film which is formed of the material is formed. It is therefore considered that a number of dangling bonds exist in a formed film. If a number of dangling bonds exist, there are problems that carriers in the inorganic element are trapped, a driving voltage is increased, and light emission efficiency is decreased.

### SUMMARY OF THE INVENTION

In view of the foregoing, it is an object of the present invention to provide a film forming method for forming a film with reduced defect. In addition, it is another object of the present invention to provide a film forming method for forming a film with a uniform quality.

It is still another object of the present invention to provide a film forming apparatus for forming a film with reduced defect. In addition, it is still another object of the present invention to provide a film forming apparatus for forming a film with a uniform quality.

It is still another object of the present invention to provide a manufacturing method of a light emitting element which can be driven with low voltage. In addition, it is still another object of the present invention to provide a manufacturing method of a light emitting element with high light emission efficiency.

The inventors of the present invention have found that, in the case of forming a film by a vapor deposition method, a problem can be solved by irradiating an evaporated substance with a laser beam or lamp light when forming a film thereof.

One aspect of the present invention is a film forming apparatus which includes a film forming chamber having an evaporation source filled with a vapor deposition material and a substrate holding unit holding a substrate so that at least a part of a surface of the substrate is exposed, and a laser beam irradiation unit emitting a laser beam; in which the laser beam irradiation unit is provided so as to irradiate the exposed surface of the substrate.

One aspect of the present invention is a film forming apparatus which includes a film forming chamber having an evaporation source filled with a vapor deposition material and a substrate holding unit holding a substrate so that at least a part of a surface of the substrate is exposed, and a laser beam irradiation unit emitting a laser beam; in which the laser beam irradiation unit is provided so as to irradiate the exposed surface of the substrate approximately perpendicularly with the laser beam.

One aspect of the present invention is a film forming apparatus which includes a film forming chamber having an evaporation source filled with a vapor deposition material and a substrate holding unit holding a substrate so that at least a part of a surface of the substrate is exposed, and a laser beam irradiation unit emitting a laser beam; in which the laser beam irradiation unit is provided so that the laser beam is emitted between the substrate and the evaporation source and so that the laser beam is emitted approximately parallel to the exposed surface of the substrate.

In the foregoing structure, the laser beam is preferably a linear laser beam. When a linear laser beam is used, a substrate having a large area can be treated by scanning the laser beam or scanning the substrate.

In the foregoing structure, it is preferable that the film forming chamber have a light introducing window and the laser beam irradiation unit be provided so that the laser beam is emitted into the film forming chamber through the light introducing window. In other words, a structure in which the film forming chamber has the light introducing window which transmits the laser beam, the laser beam irradiation unit is provided outside the film forming chamber, and the laser beam is emitted to the inside of the film forming chamber through the light introducing window is favorable. With such a structure, the structure of the film forming chamber does not become complex; therefore a film forming chamber conventionally used can be used as it is, which is advantageous.

In the foregoing structure, a wavelength of the laser beam is absorbed by the vapor deposition material. In the case of using a plurality of materials for vapor deposition (that is, in the case of co-vapor deposition), it is acceptable if the wavelength of the laser beam is absorbed by any of the plurality of vapor deposition materials.

As a laser light source of the laser beam irradiation unit, an Ar laser, a Kr laser, a carbon dioxide laser, a YAG laser, a YLF laser, a YAlO₃ laser, a GdVO₄ laser, a KGW laser, a KYW laser, an alexandrite laser, a Ti: sapphire laser, a Y₂O₃ laser, a YVO₄ laser, a helium-cadmium laser, a KrF excimer laser, an ArF excimer laser, an XeCl excimer laser, an XeF excimer laser, or the like can be specifically given.

In the foregoing film forming apparatus of the present invention, in the case of providing the film forming chamber with a window other than the light introducing window, it is preferable that a light receiving plate absorbing the laser beam be provided outside of the window to improve safety.

One aspect of the present invention is a film forming apparatus which includes a film forming chamber having an evaporation source in which a vapor deposition material is filled and a substrate holding unit holding a substrate so that at least a part of a surface of the substrate is exposed, and a lamp light source emitting lamp light; in which the lamp light source is provided so as to irradiate the exposed surface of the substrate.

In the foregoing structure, a wavelength of the lamp light is preferably absorbed by the vapor deposition material. As the lamp light source, a mercury lamp, a xenon lamp, a metal halide lamp, a halogen lamp, or the light can be specifically given.

Note that the film forming method of the present invention is particularly advantageous in co-vapor deposition in which a plurality of vapor deposition materials are evaporated at the same time to form a film in which these vapor deposition materials are mixed. Therefore, the film forming apparatus of the present invention may have a plurality of evaporation sources.

As a method of evaporating the vapor deposition material filled in the evaporation source, a method of emitting an electron beam to the vapor deposition material, a method of heating the vapor deposition material, or the like can be used. Therefore, it is preferable that the foregoing film forming apparatus be provided with an electron beam emitting unit which emits an electron beam to the vapor deposition material filled in the evaporation source, or a heating unit which heats the vapor deposition material filled in the evaporation source.

One aspect of the present invention is a film forming method which includes fixing a substrate to a substrate holding unit so that at least a part of a surface of the substrate is exposed, evaporating a vapor deposition material from an evaporation source filled with the vapor deposition material, irradiating the vapor deposition material which is evaporated with a laser beam, and depositing the vapor deposition material on the surface of the substrate.

One aspect of the present invention is a film forming method which includes fixing a substrate to a substrate holding unit so that at least a part of a surface of the substrate is exposed; evaporating a vapor deposition material from an evaporation source filled with the vapor deposition material; irradiating the vapor deposition material which is evaporated with a laser beam, by irradiating the exposed surface of the substrate approximately perpendicularly with the laser beam; and depositing the vapor deposition material on the surface of the substrate.

One aspect of the present invention is a film forming method which includes fixing a substrate to a substrate holding unit so that at least a part of a surface of the substrate is exposed; evaporating a vapor deposition material from an evaporation source filled with the vapor deposition material; irradiating the vapor deposition material which is evaporated with a laser beam, by emitting the laser beam between the substrate and the evaporation source and approximately parallel to the exposed surface of the substrate; and depositing the vapor deposition material on the surface of the substrate.

In the foregoing structure, a wavelength of the laser beam is preferably absorbed by the vapor deposition material.

One aspect of the present invention is a film forming method which includes fixing a substrate to a substrate holding unit so that at least a part of a surface of the substrate is exposed, evaporating a vapor deposition material from an evaporation source filled with the vapor deposition material, irradiating the vapor deposition material which is evaporated with lamp light, and depositing the vapor deposition material on the surface of the substrate.

In the foregoing structure, a wavelength of the lamp light is preferably absorbed by the vapor deposition material.

Note that the film forming method of the present invention is particularly advantageous in co-vapor deposition in which a plurality of vapor deposition materials are evaporated at the same time to form a film in which these vapor deposition materials are mixed.

As a method of evaporating the vapor deposition material filled in the evaporation source, a method of emitting an electron beam to the vapor deposition material, a method of heating the vapor deposition material, or the like can be used.

The foregoing film forming method can be used for manufacturing a light emitting element. A light emitting element can be manufactured by forming a first electrode, forming a light emitting layer using the foregoing film forming method, and forming the second electrode. Note that a step of forming a first insulating layer may be added after forming the first electrode. In addition, a step of forming a second insulating layer may be added after forming the light emitting layer.

One aspect of the present invention is a manufacturing method of a light emitting element, which includes forming a first electrode on a substrate, forming a vapor deposition film on the first electrode, irradiating the vapor deposition film with a laser beam, and forming a second electrode on the vapor deposition film.

One aspect of the present invention is a manufacturing method of a light emitting element, which includes forming a first electrode on a substrate, forming a vapor deposition film on the first electrode, irradiating the vapor deposition film with a laser beam while heating the vapor deposition film, and forming a second electrode on the vapor deposition film.

In any one of the foregoing aspects of the present invention, the laser beam may be again emitted to the second electrode after forming the second electrode.

In addition, the vapor deposition film may be irradiated with the laser beam from a surface side of the vapor deposition film. Alternatively, the vapor deposition film may be irradiated with the laser beam from a substrate side.

One aspect of the present invention is a manufacturing method of a light emitting element, which includes forming a first electrode on a substrate, forming a vapor deposition film on the first electrode, forming a second electrode on the vapor deposition film, and irradiating the second electrode with a laser beam.

Note that in the foregoing aspect of the present invention, the vapor deposition film contains a light emitting material.

One aspect of the present invention is a manufacturing method of a light emitting element, which includes forming a first electrode on a substrate, forming an insulating layer on the first electrode, forming a light emitting layer on the insulating layer by a vapor deposition method, irradiating the light emitting layer with a laser beam, and forming a second electrode on the light emitting layer.

One aspect of the present invention is a manufacturing method of a light emitting element, which includes forming a first electrode on a substrate, forming a light emitting layer on the first electrode by a vapor deposition method, irradiating the light emitting layer with a laser beam, forming an insulating layer on the light emitting layer, and forming a second electrode on the insulating layer.

One aspect of the present invention is a manufacturing method of a light emitting element, which includes forming a first electrode on a substrate, forming a first insulating layer on the first electrode, forming a light emitting layer on the first insulating layer by a vapor deposition method, irradiating the light emitting layer with a laser beam, forming a second insulating layer on the light emitting layer, and forming a second electrode on the second insulating layer.

Note that the light emitting layer may be irradiated with the laser beam while the light emitting layer is heated.

Note that the second electrode may be irradiated with a laser beam after forming the second electrode.

In addition, the light emitting layer may be irradiated with the laser beam from a surface side of the light emitting layer. Alternatively, the light emitting layer may be irradiated with the laser beam from a substrate side.

Further, a wavelength of the laser beam is preferably absorbed by the vapor deposition material of the light emitting layer.

As the method for forming the light emitting layer and the vapor deposition film, a method of irradiating the vapor deposition material with an electron beam to evaporate the vapor deposition material so as to be deposited, a method of heating the vapor deposition material to evaporate the vapor deposition material so as to be deposited, or the like can be used.

In the case of forming a film by a vapor deposition method, by providing a unit for forming a film with a substance by irradiating the substance that is evaporated with a laser beam or lamp light, dangling bonds of a vapor deposition material can be recombined; therefore, a film forming apparatus for forming a film with reduced strain and defect can be provided.

In the case of forming a film by a vapor deposition method, by providing a unit for irradiating a surface of the substrate where a film is to be formed with a laser beam or lamp light, dangling bonds of a vapor deposition material can be recombined and dangling bonds of a forming surface of a thin film can be reduced; therefore, a film forming apparatus for forming a film with reduced strain and defect can be provided.

By carrying out the present invention, a film forming apparatus which can form a film with reduced strain and defect can be obtained. Further, a film forming apparatus for forming a film with a uniform quality can be obtained.

By applying a film forming method and a film forming apparatus of the present invention to manufacture a light emitting element, a light emitting element with low driving voltage can be obtained. Further, a light emitting element with high light emission efficiency can be obtained.

By irradiating a vapor deposition film on a first electrode with a laser beam, a light emitting element having a light emitting layer with reduced strain and defect can be manufactured. Further, a light emitting element having a film with a uniform quality can be manufactured.

By using a manufacturing method of a light emitting element of the present invention, a light emitting element with low driving voltage can be obtained. Further, a light emitting element with high light emission efficiency can be obtained.

### BRIEF DESCRIPTION OF DRAWINGS

FIG. 1 illustrates a film forming apparatus of the present invention;

FIG. 2 illustrates a film forming apparatus of the present invention;

FIG. 3 illustrates a film forming apparatus of the present invention;

FIG. 4 illustrates a film forming apparatus of the present invention;

FIG. 5 illustrates a film forming apparatus of the present invention;

FIG. 6 illustrates a light emitting element;

FIG. 7 illustrates a light emitting element;

FIG. 8 illustrates a light emitting device;

FIGS. 9A and 9B illustrate a light emitting device;

FIGS. 10A to 10D illustrate electronic appliances;

FIG. 11 illustrates an electronic appliance;

FIGS. 12A to 12C are cross-sectional views illustrating manufacturing steps of a light emitting element of the present invention;

FIGS. 13A to 13C are cross-sectional views illustrating manufacturing steps of a light emitting element of the present invention;

FIG. 14 is a perspective view illustrating a manufacturing step of a light emitting element of the present invention;

FIGS. 15A to 15C are cross-sectional views illustrating manufacturing steps of a light emitting element of the present invention;

FIG. 16 is a cross-sectional view illustrating a film forming apparatus which can be applied to the present invention;

FIG. 17 is a perspective view illustrating a laser beam irradiation unit which can be applied to the present invention; and

FIG. 18 shows a laser beam irradiation system which can be applied to the present invention.

### DETAILED DESCRIPTION OF THE INVENTION

Hereinafter, embodiment modes of the present invention are described in detail with reference to the accompanying drawings. However, the present invention is not limited to the following description, and it is easily understood by those skilled in the art that modes and details can be modified in various ways without departing from the purpose and the scope of the present invention. Accordingly, the present invention should not be interpreted as being limited to the description of the embodiment modes to be given below.

A light emitting device in this specification includes in its category an image display device, a light emitting device, and a light source (including a lighting device). In addition, a light emitting device also includes all of a module in which a connector such as an FPC (Flexible printed circuit), a TAB (Tape Automated Bonding) tape, or a TCP (Tape Carrier Package) is attached to a panel in which a light emitting element is formed; a module in which a printed wiring board is provided on the tip of a TAB tape or a TCP; or a module in which an IC (integrated circuit) is directly mounted on a light emitting device by a COG (Chip On Glass) method.

### Embodiment Mode 1

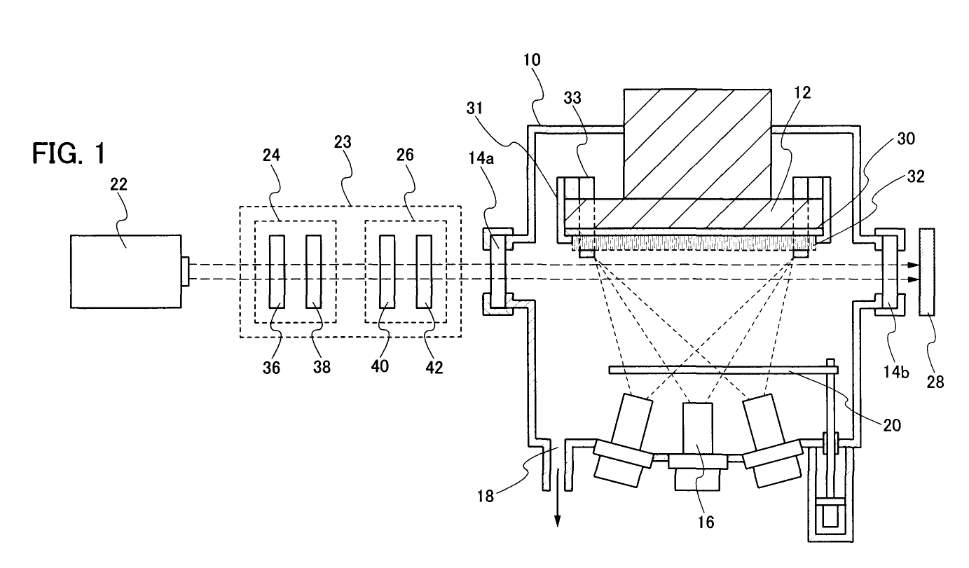

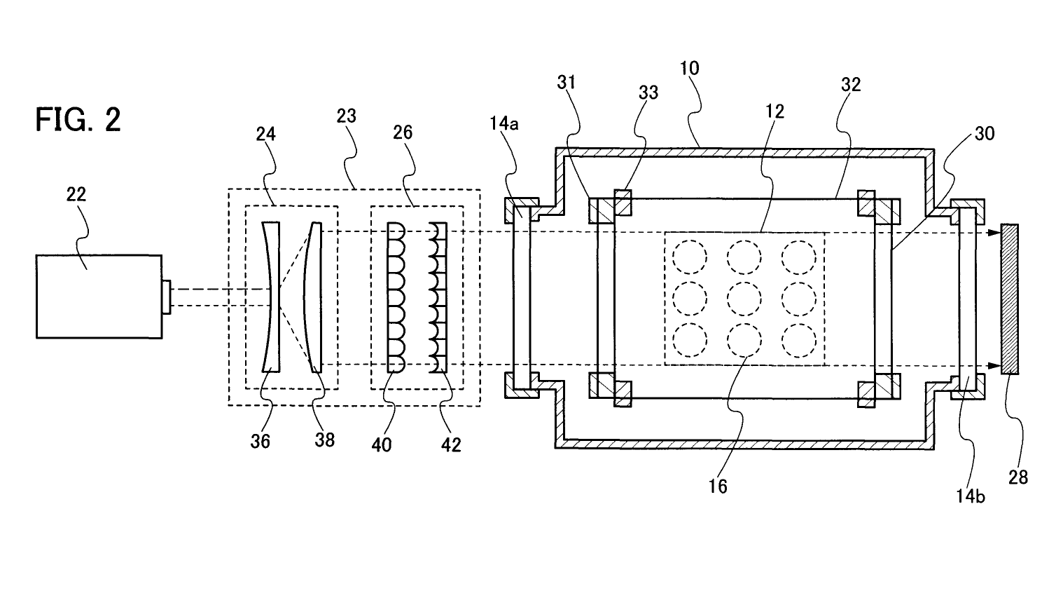

In this embodiment mode, a mode of a film forming apparatus of the present invention is described with reference to FIGS. 1 and 2. In the film forming method and the film forming apparatus described in this embodiment mode, light such as laser light is emitted in a direction parallel to a surface of a substrate or the like where a film is to be formed. FIG. 1 is a cross-sectional view illustrating a structure of the film forming apparatus and FIG. 2 is a plan view thereof. The following description is made with reference to both of the drawings.

The film forming apparatus used in this embodiment mode is structured so that a thin film which is dense and a thin film which has a uniform quality with reduced strain and defect is formed without raising a temperature to be high during film formation. Therefore, the film forming apparatus is also suitable for depositing an organic thin film which has a low evaporation temperature and a low heat-resistance temperature.

The film forming apparatus shown in FIGS. 1 and 2 is provided with a film forming chamber 10 connected to a vacuum pumping system. The film forming chamber 10 is provided with a substrate stage 12, an evaporation source 16, an exhaust port 18 connected to the vacuum pumping system, and the like. The substrate stage 12 to which a substrate and a shadow mask are fixed may be provided with a holding unit to fix them. The holding unit refers to a substrate chuck 31 which fixes a substrate 30, a mask chuck 33 which fixes a shadow mask 32 having an opening in a region where a film is to be formed, and the like. In other words, the holding unit is structured to hold the substrate 30 so that the surface or at least a part thereof is exposed to the evaporation source. The substrate chuck 31 and the mask chuck 33, using lugs at their ends, mechanically hold the substrate 30 and the shadow mask 32 by the edge portions. As another structure of the holding unit, a structure in which the holding unit holds the substrate 30 and the shadow mask 32 electromagnetically can be employed.

The substrate 30 on which a thin film is deposited is held by the holding unit of the substrate stage 12 so that it is kept approximately flat and the substrate 30 is located to face the evaporation source 16. The film forming chamber 10 is provided with a light introducing window 14a which lets a laser beam be introduced approximately parallel to the substrate 30. In other words, the light introducing window 14a for introducing a laser beam into the film forming chamber 10 is provided so that the laser beam is not emitted to a surface where a thin film is deposited.

The laser beam introduced into the film forming chamber 10 is used to act on a vapor deposition material which is evaporated or sublimed from the evaporation source 16. In the film forming apparatus shown in this embodiment mode, the evaporation source 16 and the light introducing window 14a are located so that an emitting direction of the laser beam and a scattering direction of the vapor deposition material intersect with each other. Needles to say, the location of the light introducing window 14a cannot be determined unambiguously for maintaining that relationship, and the light introducing window 14a can be arbitrarily located by using a reflecting plate or the like to the laser beam.

The laser beam preferably has a wavelength which is absorbed by the vapor deposition material. An evaporated vapor deposition material absorbs the laser beam and obtains energy. At this time, since the laser beam has energy with uniform and high density energy, the evaporated vapor deposition material irradiated with the laser beam can obtain sufficient energy. Accordingly, during the step in which the evaporated vapor deposition material loses energy and is frozen (solidified) over the substrate, the energy is lost uniformly; whereby a dense film with reduced gaps is formed.

In addition, since the vapor deposition material obtains high energy, dangling bonds generated during vapor deposition can be recombined; therefore, a film which has a uniform quality with reduced strain and defect can be formed.

It is preferable that the evaporated vapor deposition material reach the substrate while being in an excited state (that is, in a state having high energy) because a film which is denser can be formed. Also, it is preferable because a film which has further reduced strain and defect can be formed. Accordingly, the distance between the substrate and the laser beam is preferably short. The favorable distance is, for example, 0.01 to 10 mm.

In order to introduce the laser beam into the film forming chamber 10 so as to intersect with the scattering direction of the vapor deposition material, the beam shape of the laser beam preferably spreads in a direction parallel to the surface of the substrate 30 where a thin film is deposited, as shown in FIG. 2. That is, light is emitted between the evaporation source 16 and the substrate stage 12 and approximately parallel to one surface of the substrate 30. This laser beam irradiation unit includes a light source 22 and an optical system 23. As the light source 22, a laser oscillator is preferably used. In addition, the light introducing window 14a which is provided to the film forming chamber 10 is also combined therewith as an additional element. Therefore, the optical system 23 which shapes light emitted from the light source 22 is preferably provided. Although the optical system 23 is provided between the light source 22 and the light introducing window 14a, it may be provided in the film forming chamber 10.

As a structure of the optical system 23, for example, a structure in which a beam expander 24 and a beam homogenizer 26 are combined sequentially from the laser light source 22 side can be employed. The beam expander 24 includes a combination of a concave cylindrical lens 36 (or a concave lens) and a convex cylindrical lens 38 (or a convex lens), which can extend the beam width of the laser beam emitted from the laser light source 22. The laser beam is preferably a linear laser beam. With the use of a linear laser beam, a substrate having a large area can be treated by scanning the laser beam or scanning the substrate. In addition, the beam homogenizer 26 is provided for homogenizing an energy density distribution of a laser beam, for example, which is emitted by TEM00 mode and which has a Gaussian energy distribution. Therefore, as the beam homogenizer 26, a combination of a convex cylindrical lens array 40 and a concave cylindrical lens array 42 can be employed. As a result, an energy density distribution of a laser beam in a parallel direction to the surface of the substrate 30 where the thin film is deposited can be homogenized.

The laser light source 22 preferably emits a laser beam having a wavelength which is absorbed by the vapor deposition material. A laser oscillator which can emit ultraviolet light, visible light, or infrared light can be used. For example, as the laser beam, a fundamental wave (1.06 μm), a second harmonic (532 nm), or a third harmonic (355 nm) of a YVO₄ laser or a fundamental wave (10.6 μm) of a carbon dioxide laser can be applied. As a gas laser, an Ar laser, a Kr laser, a CO₂ laser, or the like can be used. As a solid-state laser, a YAG laser, a YLF laser, a YAlO₃ laser, a GdVO₄ laser, a KGW laser, a KYW laser, an alexandrite laser, a Ti: sapphire laser, a Y₂O₃ laser, a YVO₄ laser, or the like can be used. A YAG laser, a Y₂O₃ laser, a GdVO₄ laser, a YVO₄ laser, or the like is also called a ceramic laser. Alternatively, as a metal vapor laser, a helium cadmium laser or the like can be used. Further alternatively, an ultraviolet laser can be used. A typical example of an ultraviolet laser is an excimer laser, such as a KrF excimer laser (248 nm), an ArF excimer laser (193 nm), an XeCl excimer laser (308 nm), or a XeF excimer laser (351 nm). Since an excimer laser can output high power, a laser beam having high energy can be obtained. Therefore, the excimer laser can act on the vapor deposition material effectively.

As the laser light source 22, a continuous wave laser is preferably used since it can supply energy continuously. Alternatively, a pulse laser with a repetition rate of 10 MHz or more can be used. If a pulse interval is shorter than a time needed for an evaporated molecular to return to the ground state from the excited state, flux of the excited molecule can be continuously given to the surface where the thin film is deposited.

The laser beam introduced into the film forming chamber 10 irradiates a light receiving plate 28. Although the light receiving plate 28 is not essential, a light absorber may be used in order to prevent the laser beam from scattering. Further alternatively, a light reflector may be used as the light receiving plate 28 in order to make the laser beam reenter the film forming chamber 10. An optical sensor for detecting intensity of the laser beam may be provided in order to control output from the laser light source 22.

In addition, plural equivalents of the light introducing window 14a may be provided in the film forming chamber 10 so that film formation is performed with a plurality of laser beams introduced thereinto.

The evaporation source 16 can be applied to a resistance heating method using a boat formed of metal such as Ti, a ceramic crucible, or the like, an electron beam heating method, or the like. Alternatively, a molecular beam may be controlled by using Knudsen cell.

In a case where co-vapor deposition is performed using a plurality of vapor deposition materials, a plurality of the evaporation sources 16 may be provided. A shutter 20 may be provided between the evaporation source 16 and the substrate stage 12 so as to control timing at which the vapor deposition material reaches the substrate 30. The pressure in the film forming chamber 10 is not necessarily reduced, and it is acceptable if the pressure may be set within a pressure range under which vapor deposition can be carried out. Approximately, 0.01 to 0.1 Pa is preferable.

In addition, in order to form a thin film uniformly on the substrate 30, the substrate 30 or the evaporation source 16, or both the substrate 30 and the evaporation source 16 may be movably provided, and the film formation may be carried out, for example, in a raster scanning fashion. With such a structure, film formation can be easily carried out to the sixth-generation glass substrate with the outer size of 1500 mm×1800 mm, the seventh-generation glass substrate with the outer size of 1870 mm×2200 mm, and the eighth-generation glass substrate with the outer size of 2160 mm×2400 mm, which are mother glasses of a flat panel display.

In such a manner, with the use of the film forming apparatus of this embodiment mode, film formation can be carried out by irradiating evaporated molecules with a laser beam. If film formation is carried out by irradiating an evaporated vapor deposition material with a laser beam, the evaporated vapor deposition material can obtain high energy and dangling bonds of the vapor deposition material can be recombined. Therefore, a film with reduced strain and defect in which dangling bonds are reduced can be formed. Also, a dense film can be formed. It is preferable that the evaporated vapor deposition material reach the substrate while having high energy because a film having a uniform quality with further reduced strain and defect or a film with favorable crystallinity can be formed. Also, it is preferable because a denser film can be formed. Note that in this embodiment mode, although a case where a laser oscillator is used as the light source 22 is mainly described, a lamp light source such as a mercury lamp, a xenon lamp, a metal halide lamp, or a halogen lamp can be applied as the light source 22.

### Embodiment Mode 2

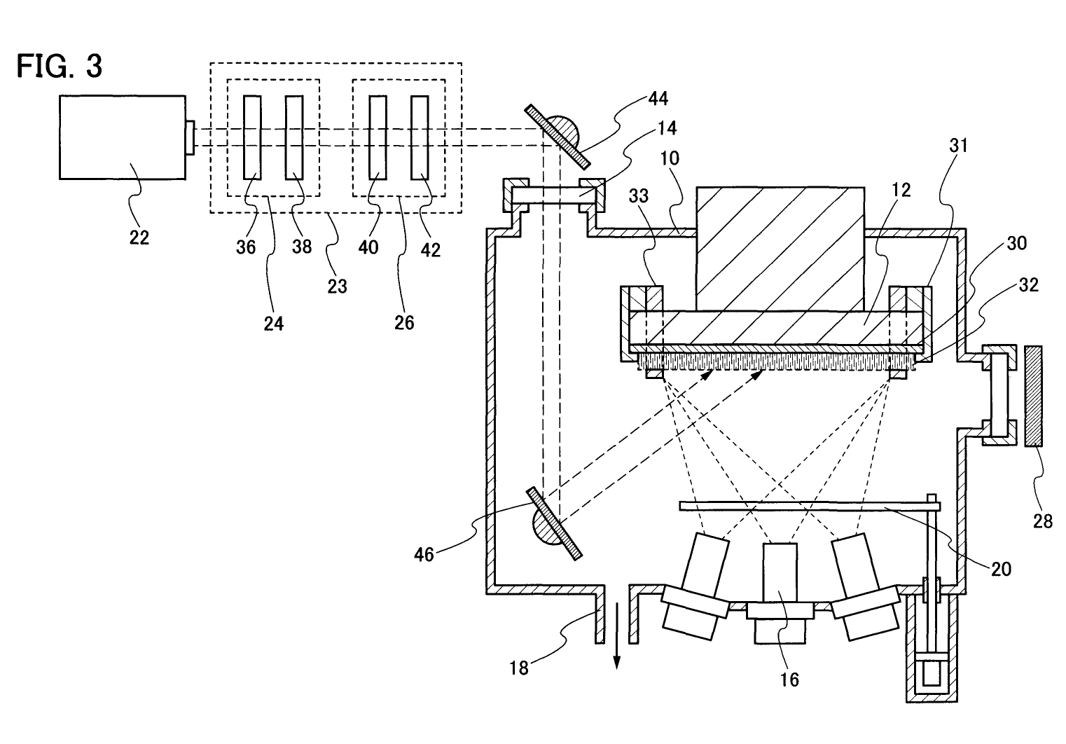

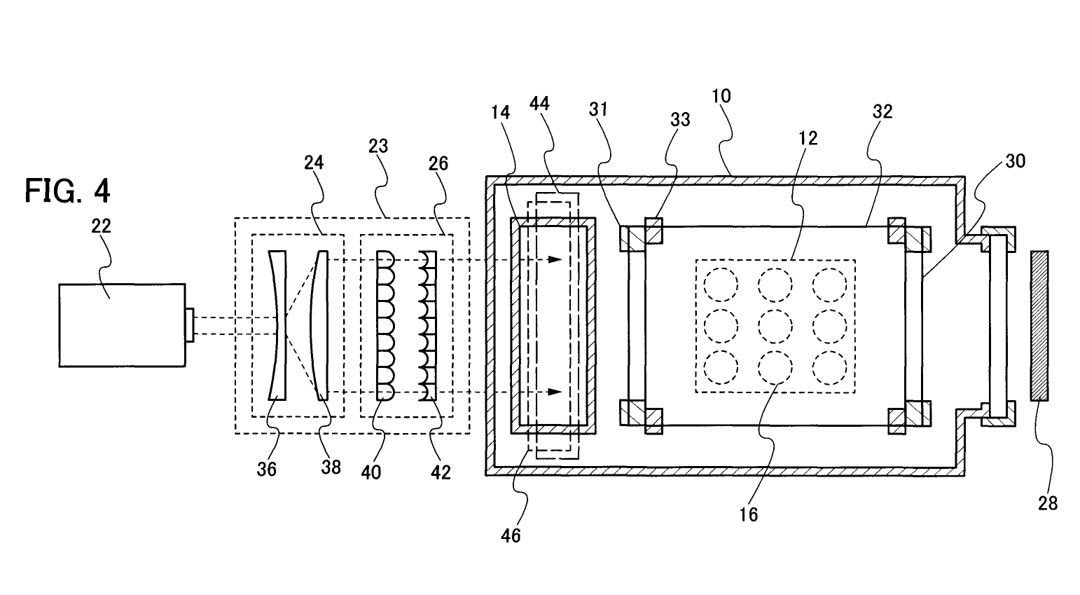

In this embodiment mode, a structure of a film forming apparatus in which a surface of a substrate where a film is to be formed can be irradiated with light such as laser light is described with reference to FIGS. 3 and 4. Note that FIG. 3 is a cross-sectional view illustrating a structure of the film forming apparatus and FIG. 4 is a plan view thereof. The description in this embodiment mode is made with reference to both of the drawings. In this embodiment mode, the same portion as that in Embodiment Mode 1 is denoted by the same reference numeral and a repeated description thereof may be omitted.

A film forming apparatus of this embodiment mode is structured so that a thin film having a favorable quality is deposited without raising a temperature to be high during film formation. Therefore, the film forming apparatus is also suitable for depositing an organic thin film which has a low evaporation temperature and a low heat-resistance temperature.

The film forming apparatus shown in FIGS. 3 and 4 is provided with the film forming chamber 10 connected to the vacuum pumping system. The film forming chamber 10 is provided with the substrate stage 12, the evaporation source 16, the exhaust port 18 connected to the vacuum pumping system, and the like, which are similar to those in Embodiment Mode 1.

The substrate 30 on which a thin film is deposited is held by the holding unit of the substrate stage 12 so that it is kept approximately flat and is located to face the evaporation source 16. In order to emit a laser beam to the substrate 30, the light source 22, the optical system 23, the light introducing window 14, and a deflecting unit are provided. The deflecting unit is used for deflecting an optical axis of the laser beam. In FIG. 3, a mirror 44 and a mirror 46 are shown as examples of the deflecting unit. In other words, the light path of the laser beam which is emitted from the light source 22, shaped by the optical system 23, and introduced into the film forming chamber 10 through the light introducing window 14 is adjusted by using the mirrors 44 and 46 so that the laser beam irradates the substrate 30. By adjusting an angle of one or both of the mirrors 44 and 46, a surface of the substrate 30 where a film is formed can be scanned by the laser beam which is shaped into, for example, a rectangle by the optical system 23 and the entire surface thereof can be irradiated with the laser beam. The laser beam is preferably a linear laser beam. With the use of a linear laser beam, a substrate having a large area can be treated by scanning the laser beam or by scanning the substrate.

In addition, plural equivalents of the light introducing window 14 shown in FIGS. 3 and 4 may be provided in the film forming chamber 10 so that film formation is performed with a plurality of laser beams introduced thereinto.

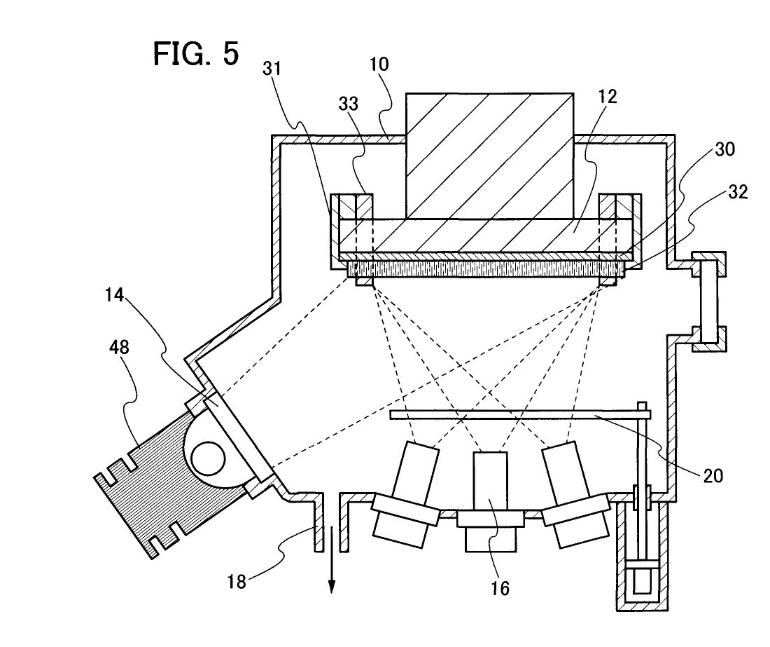

The laser beam which is introduced into the film forming chamber 10 irradiates the surface of the substrate 30 where a film is formed so as to promote a surface reaction during film formation. Although the laser beam is shaped by the optical system 23 in FIG. 3, if necessary energy can be supplied to the substrate 30, the optical system 23 can be omitted. In addition, a lamp light source 48 may be used instead of a laser beam irradiation unit. FIG. 5 is a cross-sectional view of a film forming apparatus including a lamp light source. The film forming apparatus shown in FIG. 5 has a structure in which light emitted from the lamp light source 48 irradiates the substrate 30 in the film forming chamber 10. As the lamp light source 48, a mercury lamp, a xenon lamp, a metal halide lamp, a halogen lamp, or the like can be used. Note that a lamp which emits light with a wavelength which can be absorbed by a light emitting material is preferably used as the lamp light source 48.

In such a manner, with the use of the film forming apparatus of this embodiment mode, film formation can be carried out by irradiating an evaporated vapor deposition material and a surface of the substrate with a laser beam. Therefore, high energy can be supplied to the evaporated vapor deposition material and dangling bonds of the vapor deposition material can be recombined. As a result, a film with reduced strain and defect in which dangling bonds are reduced can be formed. Also, a dense film can be formed. In addition, since the evaporated vapor deposition material reaches the substrate while having high energy, a film having a uniform quality with further reduced strain and defect, or a film with favorable crystallinity can be formed. Also, it is preferable because a denser film can be formed. Further, dangling bonds on a forming surface of the thin film can be reduced; therefore, a film with reduced strain and defect can be formed.

In this embodiment mode, unlike the structure shown in Embodiment Mode 1, the laser beam is introduced into the film forming chamber approximately parallel to the scattering direction of the vapor deposition material. In other words, the surface of the substrate is irradiated with the laser beam approximately perpendicularly. Therefore, the structure is that the laser beam is also emitted to a thin film formed on the substrate.

In the film forming apparatus in this embodiment mode, a film formed on the substrate can be irradiated with a laser beam; therefore, molecules which obtain high energy can reach the substrate while having the energy. Therefore, a film which is denser and which has a uniform quality with further reduced strain and defect can be formed. In addition, it is possible to improve a film quality of a formed film. Note that as long as a similar effect can be obtained, an angle of the laser beam may be deviated from perpendicular to the substrate.

### Embodiment Mode 3

In this embodiment mode, a light emitting material used in a light emitting element of the present invention, and a forming method of the light emitting material are described. As a light emitting material used in the present invention, a material which contains a base material and at least one kind of impurity element which serves as a light emission center can be given. Note that the impurity element does not include an element which is contained in the base material.

As a base material used for a light emitting material, sulfide, oxide, or nitride can be given. As sulfide, for example, zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), or the like can be used. As oxide, for example, zinc oxide (ZnO), yttrium oxide (Y₂O₃), or the like can be used. As nitride, for example, aluminum nitride (AlN), gallium nitride (GaN), indium nitride (InN), or the like can be used. Alternatively, zinc selenide (ZnSe), zinc telluride (ZnTe), or the like can be used. Alternatively, a ternary mixed crystal such as calcium gallium sulfide (CaGa₂S₄), strontium gallium sulfide (SrGa₂S₄), barium gallium sulfide (BaGa₂S₄), or the like can be used.

As a light emission center utilizing base electron transition of a metal ion, manganese (Mn), copper (Cu), samarium (Sm), terbium (Tb), erbium (Er), thulium (Tm), europium (Eu), cerium (Ce), or praseodymium (Pr), or the like can be used. As charge compensation, a halogen element such as fluorine (F) or chlorine (Cl) may be added.

As a light emission center utilizing donor-acceptor recombination, a light emitting material containing a first impurity element and a second impurity element can be used.

As the first impurity element, for example, copper (Cu), silver (Ag), gold (Au), platinum (Pt), silicon (Si), or the like can be used.

As the second impurity element, for example, fluorine (F), chlorine (Cl), bromine (Br), iodine (I), boron (B), aluminum (Al), gallium (Ga), indium (In), thallium (Tl), or the like can be used.

A light emitting material of the present invention can be obtained by utilizing a solid phase reaction, that is, by a method in which a base material and an impurity element are weighed, mixed in a mortar, and then heated in an electric furnace to cause a reaction, so that the base material contains impurity element. For example, a base material, the first impurity element or a compound containing the first impurity element, and the second impurity element or a compound containing the second impurity element are separately weighed, mixed in a mortar, and then heated and baked in an electric furnace. The baking temperature is preferably in the range of 700 to 1500° C. This is because if the temperature is too low, the solid phase reaction does not proceed; if the temperature is too high, the base material is decomposed. Note that although the baking may be carried out on the materials in a powder state, the baking is preferably carried out on the materials in a pellet state.

As the impurity element in the case of utilizing a solid phase reaction, a compound containing the first impurity element and the second impurity element may be contained. In this case, the impurity element is easily diffused and the solid phase reaction easily proceeds; therefore, a uniform light emitting material can be obtained. In addition, a high purity light emitting material can be obtained because an impurity element is not contained excessively. As the compound containing the first impurity element and the second impurity element, copper fluoride (CuF₂), copper chloride (CuCl), copper iodide (CuI), copper bromide (CuBr), copper nitride (Cu₃N), copper phosphide (Cu₃P), silver fluoride (AgF), silver chloride (AgCl), silver iodide (AgI), silver bromide (AgBr), gold chloride (AuCl₃), gold bromide (AuBr₃), platinum chloride (PtCl₂), or the like can be used.

Alternatively, a light emitting material containing a third impurity element instead of the second impurity element may be used.

As the third impurity element, for example, lithium (Li), sodium (Na), potassium (K), rubidium (Rb), cesium (Cs), nitrogen (N), phosphorus (P), arsenic (As), antimony (Sb), bismuth (Bi), or the like can be used.

The concentration of these impurity elements is set to be 0.01 to 10 mol %, preferably, 0.1 to 5 mol % with respect to the base material.

As a light emitting material with high electrical conductivity, a light emitting material which contains the foregoing material as a base material, and the foregoing first impurity element, second impurity element, and third impurity element can be used. The concentration of each of these impurity elements is set to be 0.01 to 10 mol %, preferably, 0.1 to 5 mol % in the base material.

As a compound containing the second impurity element and the third impurity element, for example, alkali halide such as lithium fluoride (LiF), lithium chloride (LiCl), lithium iodide (LiI), copper bromide (LiBr), or sodium chloride (NaCl); boron nitride (BN); aluminium nitride (AlN); aluminium antimonide (AlSb); gallium phosphide (GaP); gallium arsenide (GaAs); indium phosphide (InP); indium arsenide (InAs); indium antimonide (InSb); or the like can be used.

A light emitting layer using a light emitting material which contains the foregoing material as a base material, and the foregoing first impurity element, second impurity element, and third impurity element can emit light without requiring a hot electron accelerated by a high electric field. That is, there is no need to apply high voltage to a light emitting element; therefore, a light emitting element which can operate with low driving voltage can be obtained. In addition, since it can emit light with low driving voltage, a light emitting element with reduced power consumption can be obtained.

By further adding an impurity element to the foregoing light emitting material, a crystal system of the light emitting material can be controlled. As an impurity which can control the crystal system; GaP, GaAs, GaSb, InP, InAs, InSb, Si, Ge, and like can be given as an impurity for forming the cubic crystal system. As an impurity for forming the hexagonal crystal system, GaN and InN can be given. Alternatively, AlP, AlN, AlSb, and the like can be given. By controlling the crystal system of the light emitting material, light emission efficiency can be improved.

In addition, a method for forming the light emitting material is not limited to a solid phase reaction, and a method in which the base material contains an impurity element can be appropriately used.

A film of the foregoing light emitting material is formed by a resistance heating vapor deposition method, an electron beam (EB) vapor deposition method, or the like and can be used as a light emitting layer of a light emitting element. When forming the film of the light emitting material, the material is vapor deposited while being irradiated with a laser beam or lamp light. In specific, the film forming apparatus and the film forming method shown in Embodiment Mode 1 or 2 can be used. With the use of the film forming apparatus and the film forming method shown in Embodiment Mode 1 or 2, dangling bonds generated during vapor deposition can be recombined, so that a film having a dense film quality with reduced strain and defect can be obtained. In particular, by emitting a laser beam or lamp light approximately parallel to the vapor deposition direction as shown in Embodiment Mode 2, a film quality of a formed film can be improved; therefore, a film having a uniform quality with further reduced strain and defect can be formed. Accordingly, carrier trapping in the light emitting layer by the dangling bonds can be suppressed. As a result, the collision excitation probability of the light emission center is improved, which can improve the light emission efficiency. In addition, since carrier trapping in the light emitting layer by the dangling bonds can be suppressed, driving voltage of the light emitting element can be reduced.

### Embodiment Mode 4

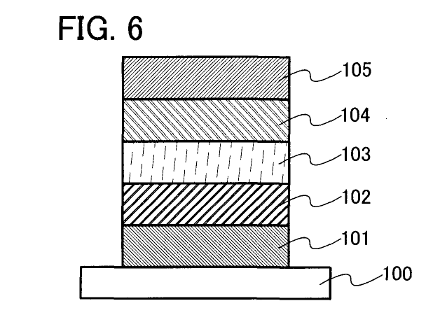

In this embodiment mode, a mode of a manufacturing method of a light emitting element of the present invention is described with reference to FIG. 6.

A light emitting element described in this embodiment mode has an element structure including a first electrode 101 and a second electrode 105; a first insulating layer 102 and a second insulating layer 104 which are in contact with the first electrode 101 and the second electrode 105, respectively; and a light emitting layer 103 between the first insulating layer 102 and the second insulating layer 104, over a substrate 100. The light emitting element described in this embodiment mode can emit light when voltage is applied between the first electrode 101 and the second electrode 105, and it can operate either by DC driving or AC driving.

The substrate 100 is used as a support body of the light emitting element. As the substrate 100, a glass substrate, a plastic substrate, a ceramic substrate, a metal substrate having an insulating layer on its surface, or the like can be used appropriately. Note that another material which serves as a support body during manufacturing steps of the light emitting element can be used.

The first electrode is formed over the substrate 100. As the first electrode 101, various kinds of metal, alloy, and conductive compound, a mixture thereof, or the like can be used. In specific, indium oxide-tin oxide (ITO: Indium Tin Oxide), indium oxide-tin oxide containing silicon or silicon oxide, indium oxide-zinc oxide (IZO: Indium Zinc Oxide), indium oxide containing tungsten oxide and zinc oxide (IWZO), or the like can be given as an example. Theses conductive metal oxide films are generally formed by sputtering. For example, indium oxide-zinc oxide (IZO) can be formed by sputtering using a target in which 1 to 20 wt % of zinc oxide with respect to indium oxide is contained. Indium oxide containing tungsten oxide and zinc oxide (IWZO) can be formed by sputtering using a target in which 0.5 to 5 wt % of tungsten oxide and 0.1 to 1 wt % of zinc oxide with respect to indium oxide are contained. Alternatively, aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), nitride of a metal material (such as titanium nitride: TiN), or the like can be used. Note that in a case where the first electrode 101 or the second electrode 105 is a light transmitting electrode, although a material which has low visible light transmittance is used, the material can be used as a light transmitting electrode by forming a film thereof to have a film thickness of approximately 1 to 50 nm, preferably, 5 to 20 nm. Note that the electrode can be formed by using a vacuum vapor deposition, CVD, or sol-gel method instead of sputtering.

Then, the first insulating layer 102 is formed on the first electrode 101. The first insulating layer 102 is not particularly limited, but it preferably has high insulation resistance and a dense film quality. Furthermore, it preferably has a high dielectric constant. For example, silicon oxide (SiO₂), yttrium oxide (Y₂O₃), titanium oxide (TiO₂), aluminum oxide (Al₂O₃), hafnium oxide (HfO₂), tantalum oxide (Ta₂O₅), barium titanate (BaTiO₃), strontium titanate (SrTiO₃), lead titanate (PbTiO₃), silicon nitride (Si₃N₄), zirconium oxide (ZrO₂), or the like, a mixed film thereof, or a stacked films including two or more kinds of these films can be used. These insulating films can be formed by sputtering, vapor deposition, CVD, or the like. The film thickness of the first insulating layer 102 is not particularly limited, but is preferably set in the range of 10 to 1000 nm. Note that since the light emitting element of this embodiment mode does not always require a hot electron, there is an advantage that its thickness and driving voltage can be reduced. The film thickness is preferably 500 nm or less, more preferably, 100 nm or less.

The light emitting layer 103 is formed on the first insulating layer 102. The light emitting layer 103 is a layer containing the light emitting material shown in Embodiment Mode 3. The light emitting layer 103 can be formed using the film forming apparatus and the film forming method shown in Embodiment Mode 1 or 2. The film thickness of the light emitting layer 103 is not particularly limited but is preferably in the range of 10 to 1000 nm.

Then, the second insulating film 104 is formed. The second insulating layer 104 is not particularly limited, but it preferably has high insulation resistance and a dense film quality. Furthermore, it preferably has a high dielectric constant. For example, silicon oxide (SiO₂), yttrium oxide (Y₂O₃), titanium oxide (TiO₂), aluminum oxide (Al₂O₃), hafnium oxide (HfO₂), tantalum oxide (Ta₂O₅), barium titanate (BaTiO₃), strontium titanate (SrTiO₃), lead titanate (PbTiO₃), silicon nitride (Si₃N₄), zirconium oxide (ZrO₂), or the like; a mixed film thereof; or stacked films including two or more kinds of these films can be used. These insulating films can be formed by sputtering, vapor deposition, CVD, or the like. The film thickness of the second insulating layer 104 is not particularly limited, but is preferably set in the range of 10 to 1000 nm. Note that since the light emitting element of this embodiment mode does not always require a hot electron, there is an advantage that its thickness and driving voltage can be reduced. The film thickness is preferably 500 nm or less, more preferably, 100 nm or less.

The second electrode 105 is formed. As the second electrode 105, various kinds of metal, alloy, and conductive compound, a mixture thereof, or the like can be used. In specific, indium oxide-tin oxide (ITO: Indium Tin Oxide), indium oxide-tin oxide containing silicon or silicon oxide, indium oxide-zinc oxide (IZO: Indium Zinc Oxide), indium oxide containing tungsten oxide and zinc oxide (IWZO), or the like can be given as an example. Theses conductive metal oxide films are generally formed by sputtering. For example, indium oxide-zinc oxide (IZO) can be formed by sputtering using a target in which 1 to 20 wt % of zinc oxide with respect to indium oxide is contained. Indium oxide containing tungsten oxide and zinc oxide (IWZO) can be formed by sputtering using a target in which 0.5 to 5 wt % of tungsten oxide and 0.1 to 1 wt % of zinc oxide with respect to indium oxide are contained. Alternatively, aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), nitride of a metal material (such as titanium nitride: TiN), or the like can be used. Note that in a case where the first electrode 101 or the second electrode 105 is a light transmitting electrode, although a material which has low visible light transmittance is used, the material can be used as a light transmitting electrode by forming a film thereof to have a film thickness of approximately 1 to 50 nm, preferably, 5 to 20 nm. Note that the electrode can be formed by using a vacuum vapor deposition, CVD, or sol-gel method instead of sputtering.

Note that since light emission is taken outside through the first electrode 101 or the second electrode 105, it is necessary that at least one of the first electrode 101 and the second electrode 105 transmits light.

Although not shown, a buffer layer may be provided between the light emitting layer and the insulating layer. The buffer layer has a role to facilitate injection of carriers and to suppress mixing of layers. The buffer layer is not particularly limited. For example, ZnS, ZnSe, ZnTe, CdS, SrS, BaS, or the like which is the base material in the light emitting layer; CuS; Cu₂S; or alkali halide such as LiF, CaF₂, BaF₂, or MgF₂ can be used.

A light emitting element of the present invention has a light emitting layer with reduced strain and defect. Therefore, a light emitting element with high light emission efficiency and low driving voltage can be obtained. In addition, a light emitting element with reduced power consumption can be obtained since the light emission efficiency is heightened and the driving voltage is lowered.

Note that this embodiment mode can be appropriately combined with another embodiment mode.

### Embodiment Mode 5

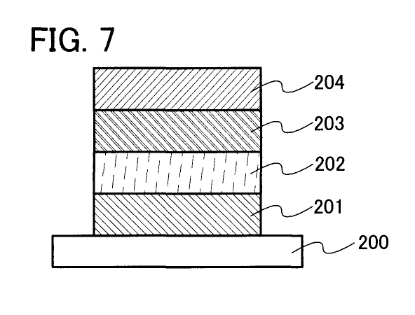

In this embodiment mode, a mode of a manufacturing method of a light emitting element of the present invention is described with reference to FIG. 7.

The light emitting element shown in this embodiment mode has an element structure including a first electrode 201, a second electrode 204, an insulating layer 203 being in contact with the second electrode 204, and a light emitting layer 202 between the first electrode 201 and the insulating layer 203, over a substrate 200. A light emitting element described in this embodiment mode can emit light when voltage is applied between the first electrode 201 and the second electrode 204, and it can operate either by DC driving or AC driving.

The substrate 200 is used as a support body of the light emitting element. As the substrate 200, a glass substrate, a plastic substrate, a ceramics substrate, a metal substrate having an insulating layer on its surface, or the like can be used appropriately. Note that another material which serves as a support body during manufacturing steps of the light emitting element can be used.

The first electrode 201 is formed over the substrate 200. As the first electrode 201, various kinds of metal, alloy, and conductive compound, a mixture thereof, or the like can be used. In specific, indium oxide-tin oxide (ITO: Indium Tin Oxide), indium oxide-tin oxide containing silicon or silicon oxide, indium oxide-zinc oxide (IZO: Indium Zinc Oxide), indium oxide containing tungsten oxide and zinc oxide (IWZO), or the like can be given as an example. These conductive metal oxide films are generally formed by sputtering. For example, indium oxide-zinc oxide (IZO) can be formed by sputtering using a target in which 1 to 20 wt % of zinc oxide with respect to indium oxide is contained. Indium oxide containing tungsten oxide and zinc oxide (IWZO) can be formed by sputtering using a target in which 0.5 to 5 wt % of tungsten oxide and 0.1 to 1 wt % of zinc oxide with respect to indium oxide are contained. Alternatively, aluminium (Al), silver (Ag), gold (Au), platinum (Pt), nickel (Ni), tungsten (W), chromium (Cr), molybdenum (Mo), iron (Fe), cobalt (Co), copper (Cu), palladium (Pd), nitride of a metal material (such as titanium nitride: TiN), or the like can be used. Note that in a case where the first electrode 201 or the second electrode 204 is a light transmitting electrode, although a material which has low visible light transmittance is used, the material can be used as a light transmitting electrode by forming a film thereof to have a film thickness of approximately 1 to 50 nm, preferably 5 to 20 nm. Note that the electrode can be formed by using a vacuum vapor deposition, CVD, or sol-gel method instead of sputtering.

Then, the light emitting layer 202 is formed. The light emitting layer 202 is a layer containing the light emitting material shown in Embodiment Mode 3. The light emitting layer 202 can be formed using the film forming apparatus and the film forming method shown in Embodiment Mode 1 or 2. The thickness of the light emitting layer 202 is not particularly limited but is preferably in the range of 10 to 1000 nm.

Then, the insulating layer 203 is formed. The insulating layer 203 is not particularly limited, but it preferably has high insulation resistance and a dense film quality. Furthermore, it preferably has a high dielectric constant. For example, silicon oxide (SiO₂), yttrium oxide (Y₂O₃), titanium oxide (TiO₂), aluminum oxide (Al₂O₃), hafnium oxide (HfO₂), tantalum oxide (Ta₂O₅), barium titanate (BaTiO₃), strontium titanate (SrTiO₃), lead titanate (PbTiO₃), silicon nitride (Si₃N₄), zirconium oxide (ZrO₂), or the like; a mixed film thereof; or stacked films including two or more kinds of these films can be used. These insulating films can be formed by sputtering, vapor deposition, CVD, or the like. The film thickness of the insulating layer 203 is not particularly limited, but is preferably set in the range of 10 to 1000 nm. Note that since the light emitting element of this embodiment mode does not always require a hot electron, there is an advantage that its thickness and driving voltage can be reduced. The film thickness is preferably 500 nm or less, more preferably, 100 nm or less.

The second electrode 204 is formed. As the second electrode 204, various kinds of metal, alloy, and conductive compound, or a mixture thereof can be used. In specific, indium oxide-tin oxide (ITO: Indium Tin Oxide), indium oxide-tin oxide containing silicon or silicon oxide, indium oxide-zinc oxide (IZO: Indium Zinc Oxide), indium oxide containing tungsten oxide and zinc oxide (IWZO), or the like can be given as an example. Theses conductive metal oxide films are generally formed by sputtering. For example, indium oxide-zinc oxide (IZO) can be formed by sputtering using a target in which 1 to 20 wt % of zinc oxide with respect to indium oxide is contained. Indium oxide containing tungsten oxide and zinc oxide (IWZO) can be formed by sputtering using a target in which 0.5 to 5 wt % of tungsten oxide and 0.1 to 1 wt % of zinc oxide with respect to indium oxide are contained. Alternatively, aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), nitride of a metal material (such as titanium nitride: TiN), or the like can be used. Note that in a case where the first electrode 201 or the second electrode 204 is a light transmitting electrode, although a material which has low visible light transmittance is used, the electrode can be used as a light transmitting electrode by forming a film thereof to have a film thickness of approximately 1 to 50 nm, preferably, 5 to 20 nm. Note that the electrode can be formed by using a vacuum vapor deposition, CVD, or sol-gel method instead of sputtering.

Note that light emission is taken outside through the first electrode 201 or the second electrode 204, at least one of the first electrode 201 and the second electrode 204 transmits light.

Although not shown, a buffer layer may be provided between the light emitting layer and the insulating layer, or between the light emitting layer and the electrode. The buffer layer has a role to facilitate injection of carriers and to suppress mixing of layers. The buffer layer is not particularly limited. For example, ZnS, ZnSe, ZnTe, CdS, SrS, BaS, or the like which is the base material in the light emitting layer; CuS; Cu₂S; or alkali halide metal such as LiF, CaF₂, BaF₂, or MgF₂ can be used.

In addition, although the insulating layer 203 is provided so as to be in contact with the second electrode 204 in FIG. 7, the insulating layer 203 may be provided to be in contact with the first electrode 201 by reversing the order of the insulating layer and the light emitting layer.

A light emitting element of the present invention has a light emitting layer with reduced strain and defect. Therefore, a light emitting element with high light emission efficiency and low driving voltage can be obtained. In addition, a light emitting element with reduced power consumption can be obtained since the light emission efficiency is heightened and the driving voltage is lowered.

Note that this embodiment mode can be appropriately combined with another embodiment mode.

### Embodiment Mode 6

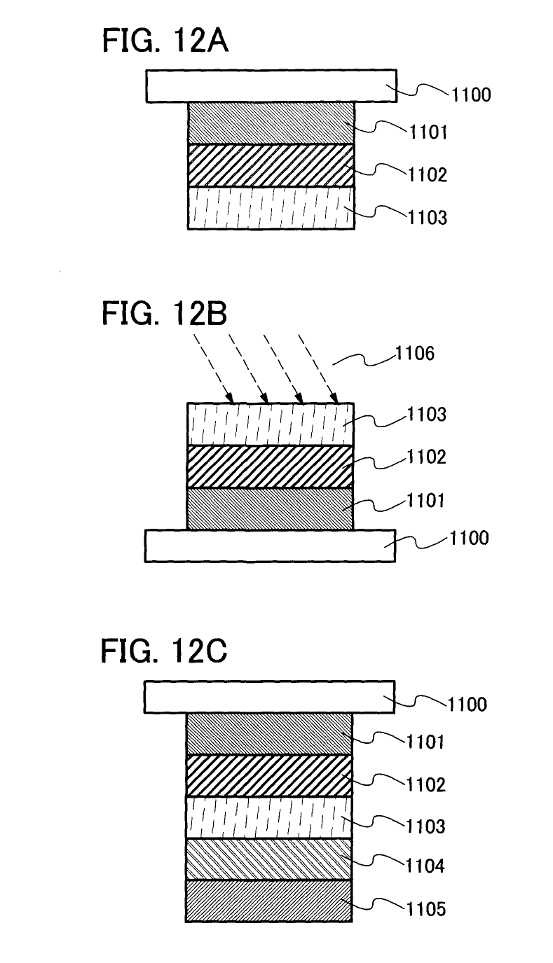

In this embodiment mode, a manufacturing method of a light emitting element, which is different from those shown in Embodiment Modes 4 and 5 is described with reference to FIGS. 12A to 12C, 16, and 17.

As shown in FIG. 12A, a first electrode 1101 is formed on a substrate 1100, a first insulating layer 1102 is formed on the first electrode 1101, and a light emitting layer 1103 is formed on the first insulating layer 1102.

The substrate 1100 is used as a support body of the light emitting element. As the substrate 1100, any of the substrates listed in Embodiment Mode 4 as the substrate 100 can be appropriately used.

The first electrode 1101 is formed on the substrate 1100. The first electrode 1101 can be formed using a material and a manufacturing method similar to those of the first electrode 101 in Embodiment Mode 4.

Then, the first insulating layer 1102 is formed. The first insulating layer 1102 can be formed using a material and a manufacturing method similar to those of the first insulating layer 102 in Embodiment Mode 4.

The light emitting layer 1103 can be formed by depositing the light emitting material shown in Embodiment Mode 3 by a vacuum vapor deposition method such as a resistance heating vapor deposition method or an electron beam vapor deposition (an EB vapor deposition) method, or a physical vapor deposition (PVD) method such as a sputtering method. Alternatively, the layer containing the foregoing light emitting material can be formed by using a chemical vapor deposition (CVD) method such as a metal organic CVD method or a low-pressure hydride transport CVD method, or an atomic layer epitaxy (ALE) method, or the like. Further alternatively, the light emitting layer 1103 can be formed by applying a composition in which the foregoing light emitting material is dispersed using an ink jet method, a spin coating method, a printing method, or the like; and baking the composition thereafter. The film thickness of the light emitting layer 1103 is not particularly limited, but is preferably in the range of 10 to 1000 nm.

Although not shown, a buffer layer may be provided between the light emitting layer and the insulating layer. The buffer layer has a role to facilitate injection of carriers and to suppress mixing of layers. The buffer layer is not particularly limited. For example, ZnS, ZnSe, ZnTe, CdS, SrS, BaS, or the like which is the base material in the light emitting layer; CuS; Cu₂S; or alkali halide such as LiF, CaF₂, BaF₂, or MgF₂ can be used.

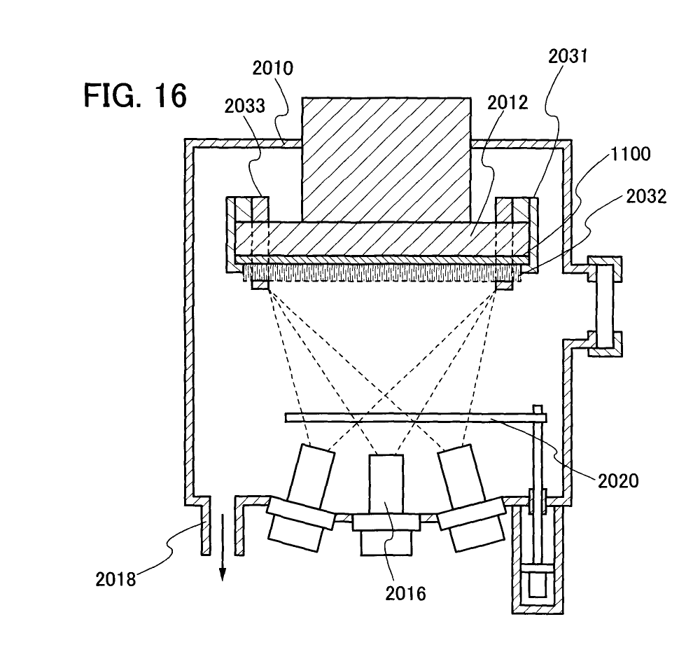

Here, a film forming apparatus shown in FIG. 16 is used and the first electrode 1101 is formed on the substrate 1100, the first insulating layer 1102 is formed on the first electrode 1101, and the light emitting layer 1103 is formed on the first insulting layer 1102.

Hereinafter, a structure of the film forming apparatus shown in FIG. 16 is described. FIG. 16 is a cross-sectional view illustrating a structure of the film forming apparatus.

The film forming apparatus shown in FIG. 16 is provided with a film forming chamber 2010 connected to a vacuum pumping system. The film forming chamber 2010 is provided with a substrate stage 2012, an evaporation source 2016, an exhaust port 2018 connected to the vacuum pumping system, and the like. The substrate stage 2012 to which a substrate and a shadow mask are fixed may be provided with a holding unit to fix them. The holding unit refers to a substrate chuck 2031 which fixes a substrate 1100, a mask chuck 2033 which fixes a shadow mask 2032 having an opening in a region where a film is to be formed, and the like. In other words, the holding unit is structured to hold the substrate 1100 so that and the surface or at least a part thereof is exposed to the evaporation source. The substrate chuck 2031 and the mask chuck 2033, using lugs at their ends, mechanically hold the substrate 1100 and the shadow mask 2032 by the edge portions. As another structure of the holding unit, a structure in which the holding unit holds the substrate 1100 and the shadow mask 2032 electromagnetically can be employed.

The substrate 1100 on which a vapor deposition film is formed is held by the holding unit of the substrate stage 2012 so that it is kept approximately flat and the substrate 1100 is located to face the evaporation source 2016.

The evaporation source 2016 can be applied to a resistance heating method using a boat formed of metal such as Ti, a ceramic crucible, or the like, an electron beam heating method, or the like. Alternatively, a molecular beam may be controlled by using Knudsen cell. Further alternatively, an evaporation source may be used in which a vapor deposition material is irradiated with a laser beam to be evaporated. Still further alternatively, an evaporation source may have a rectangular shape and may be irradiated with a linearly shaped laser beam to be heated.

In a case where co-vapor deposition is performed using a plurality of vapor deposition materials, a plurality of the evaporation sources 2106 may be provided. A shutter 2020 may be provided between the evaporation source 2016 and the substrate stage 2012 so as to control timing at which the vapor deposition material reaches the substrate 1100. The pressure in the film forming chamber 2010 is not necessarily reduced and it is acceptable if the pressure may be set within a pressure range under which vapor deposition can be carried out. Approximately, 0.01 to 0.1 Pa is preferable.

In addition, in order to form a thin film uniformly on the substrate 1100, the substrate 1100 or the evaporation source 2016, or both the substrate 1100 and the evaporation source 2016 may be movably provided, and the film formation may be carried out, for example, in a raster scanning fashion. With such a structure, film formation can be easily carried out to the sixth-generation glass substrate with the outer size of 1500 mm×1800 mm, the seventh-generation glass substrate with the outer size of 1870 mm×2200 mm, and the eighth-generation glass substrate with the outer size of 2160 mm×2400 mm, which are mother glasses of a flat panel display.

In the evaporation source 2016 of the foregoing film forming apparatus, boats formed of metal or crucibles filled with vapor deposition materials for forming the first electrode 1101, the first insulating layer 1102, and the light emitting layer 1103 are located. Then, the vapor deposition material of the first electrode 1101 is vapor deposited on the substrate 1100. Then, the vapor deposition material of the first insulating layer 1102 is vapor deposited on the first electrode 1101. After that, the vapor deposition material of the light emitting layer 1103 is vapor deposited on the first insulating layer 1102.

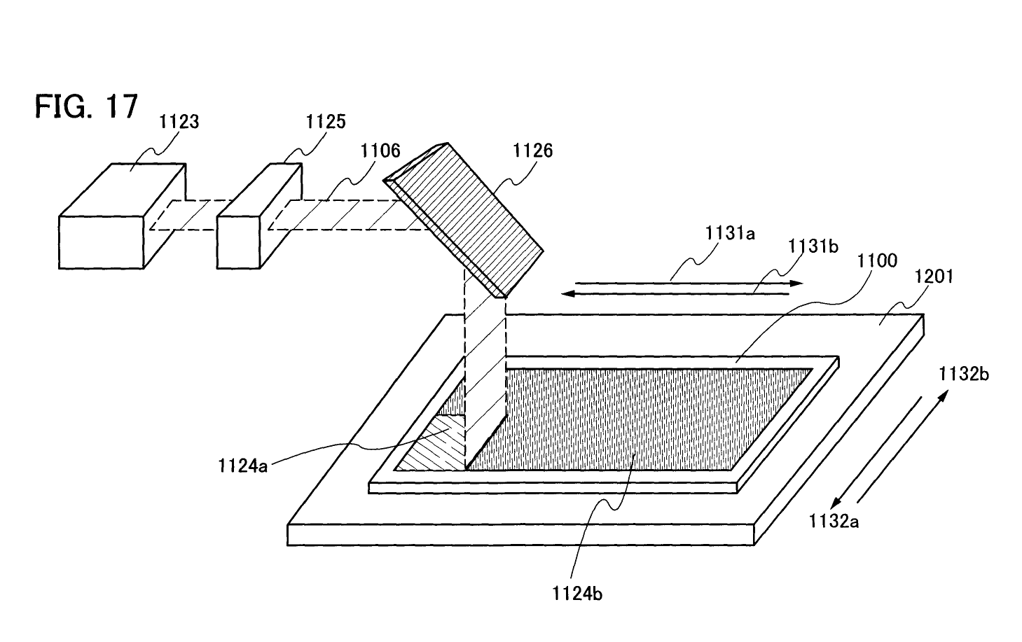

Subsequently, as shown in FIGS. 12B and 17, a laser beam 1106 emitted from the laser beam irradiation unit irradiates the first electrode, the first insulating layer, and the light emitting layer formed on the substrate 1100. Note that in FIG. 17, a region 1124a shows a region in which any of the first electrode, the first insulating layer, or the light emitting layer is irradiated with the laser beam. On the other hand, a region 1124b shows a region in which the first electrode, the first insulating layer, and the light emitting layer are not irradiated with the laser beam.

A laser beam irradiation unit which can be used in this embodiment mode is described with reference to FIG. 17. The laser beam irradiation unit is provided with a moving table 1201, a light source 1123, an optical system 1125, and a deflecting unit 1126. The deflecting unit 1126 is used for deflecting an optical axis of laser beam and a mirror is given as an example in FIG. 17. In other words, the light path of the laser beam which is emitted from the light source 1123, shaped by the optical system 1125, and emitted over the substrate 1100, is adjusted by using the deflecting unit 1126 so that the laser beam irradiates the substrate 1100. By adjusting an angle of the deflecting unit 1126, the laser beam which is shaped into, for example, a rectangular shape by the optical system 1125 can be scanned over the surface of the substrate 1100 where a film is formed, so that the entire surface can be irradiated. Alternatively, the deflecting unit 1126 may be fixed and the moving table 1201 can be moved to any direction indicated by arrows 1131a, 1131b, 1132a, and 1132b so that the surface of the substrate 1100 where a film is formed can be irradiated with the laser beam.

As the light source 1123, a laser oscillator is preferably used. In addition, it is preferable to provide the optical system 1125 to shape light emitted from the light source 1123. The optical system 1125 is provided between the light source 1123 and the substrate 1100.

As a structure of the optical system 1125, for example, a structure in which a beam expander and a beam homogenizer are combined sequentially from the light source side 1123 can be employed. The beam expander includes a combination of a concave cylindrical lens (or a concave lens) and a convex cylindrical lens (or a convex lens), which can extend the beam width of the laser beam emitted from the light source 1123. The beam homogenizer is provided for homogenizing an energy density distribution of laser beam which is emitted, for example, by TEM00 mode and which has a Gaussian energy distribution. Therefore, as the beam homogenizer, a combination of a concave cylindrical lens array and a convex cylindrical lens array can be employed. Accordingly, an energy density distribution of a laser beam in a parallel direction to the surface of the substrate 1100 where the thin film is deposited can be homogenized.

A laser oscillator applied as the light source 1123 preferably emits light having a wavelength which can be absorbed by the vapor deposition material, and a gas laser, a solid-state laser, or the like can be used. For example, a fundamental wave (1.06 μm), a second harmonic (532 nm), or a third harmonic (355 nm) of a YVO₄ laser or a fundamental wave (10.6 μm) of a carbon dioxide laser can be given. As a gas laser, an Ar laser, a Kr laser, a CO₂ laser, or the like can be given. As a solid-state laser, a YAG laser, a YLF laser, a YAlO₃ laser, a GdVO₄ laser, a KGW laser, a KYW laser, an alexandrite laser, a Ti: sapphire laser, a Y₂O₃ laser, a YVO₄ laser, or the like can be given. A YAG laser, a Y₂O₃ laser, a GdVO₄ laser, a YVO₄ laser, or the like is also called a ceramic laser. Alternatively, as a metal vapor laser, a helium cadmium laser or the like can be used. Further alternatively, an ultraviolet laser can be used. A typical example of an ultraviolet laser is an excimer laser, such as a KrF excimer laser (248 nm), an ArF excimer laser (193 nm), an XeCl excimer laser (308 nm), or a XeF excimer laser (351 nm). Since an excimer laser can output high power, laser beam having high energy can be obtained. Therefore, the excimer laser can act on the vapor deposition material effectively.

As the light source 1123, a continuous wave laser is preferably used since it can supply energy continuously. Alternatively, a pulse laser with a repetition rate of 10 MHz or more can be used. If a pulse interval is shorter than a time needed for an evaporated molecule to return to the ground state from the excited state, flux of the excited molecular can be continuously given to the surface where the thin film is deposited.

An optical sensor for detecting intensity of the laser beam may be provided at any location of the laser beam irradiation unit so that output from the light source 1123 may be controlled.

In addition, plural equivalents of the light source 1123, the optical system 1125, and deflecting unit 1126 may be provided so that a plurality of laser beams are emitted to the same region at the same time. Alternatively, a plurality of laser beams may be emitted to the same region separately.

As described above, by emitting laser beam to the light emitting layer using the film forming apparatus and the laser beam irradiation unit of this embodiment mode, a light emitting layer formed of a thin film which is dense, a thin film which has a uniform film quality with reduced strain and defect, or a thin film which has favorable crystallinity can be formed. In specific, dangling bonds generated during vapor deposition can be recombined, so that a film with reduced strain and defect and with dense film quality can be obtained. Accordingly, carrier trapping in the light emitting layer by the dangling bonds can be suppressed. As a result, the collision excitation probability of the light emission center is improved, which can improve the light emission efficiency. In addition, since carrier trapping in the light emitting layer by the dangling bonds can be suppressed, driving voltage of the light emitting element can be reduced.

Subsequently, as shown in FIG. 12C, the second insulating layer 1104 and the second electrode 1105 are formed on the light emitting layer 1103. The second insulating layer 1104 can be formed using a material and a forming method similar to those of the first insulating layer 1102. In addition, the second electrode 1105 can be formed using a material and a forming method similar to those of the first electrode 1101.

Here, the substrate 1100 is set again in the film forming apparatus shown in FIG. 16. A vapor deposition material of the second insulating layer 1104 is vapor deposited so that the second insulating layer 1104 is formed on the light emitting layer 1103. Then, a vapor deposition material of the second electrode 1105 is vapor deposited so that the second electrode 1105 is formed on the second insulating layer 1104. Note that since light emission from the light emitting element is taken outside through the first electrode 1101 or the second electrode 1105, it is necessary that at least one of the first electrode 1101 and the second electrode 1105 is formed of a light-transmitting material.

Note that in FIG. 12B, the laser beam 1106 may be emitted after sequentially forming the first electrode 1101, the first insulating layer 1102, the light emitting layer 1103, and the second insulating layer 1104 on the substrate 1101. After that, the second electrode 1105 is formed on the second insulating layer 1104.

Alternatively, the laser beam 1106 may be emitted after sequentially forming the first electrode 1101, the first insulating layer 1102, the light emitting layer 1103, the second insulating layer 1104, and the second electrode 1105 on the substrate 1100. In this case, the second electrode 1105 preferably transmits light.

Further, in this embodiment mode, although the laser beam irradiates the second insulating layer 1104 side in FIG. 12B, instead of performing this step, the laser beam 1106 may be emitted to the first electrode 1101, the first insulating layer 1102, and the light emitting layer 1103 through the substrate 1100. Note that in this case, the substrate 1100 and the first electrode 1101 preferably transmit light. With the first insulating layer 1102 and the light emitting layer 1103 being irradiated with the laser beam 1106 through the substrate 1100, any of these layers can be prevented from being peeled off due to energy of the laser beam.

Furthermore, the laser beam may irradiate any of the first electrode 1101, the first insulating layer 1102, the light emitting layer 1103, the second insulating layer 1104, or the second electrode 1105, preferably, the light emitting layer 1103 more than once. By emitting the laser beam more than once, a thin film which is denser, a thin film having a uniform quality with further reduced strain and defect, or a thin film which has more favorable crystallinity can be formed.

By performing the foregoing steps, a light emitting element including a thin film which is dense, a thin film which has a uniform quality with reduced strain and defect, or a thin film which has favorable crystallinity can be manufactured. Also, a light emitting element with high light emission efficiency can be manufactured.

### Embodiment Mode 7

In this embodiment mode, steps of manufacturing a light emitting element using a film forming apparatus having a laser beam irradiation unit are described with reference to FIGS. 13, 3, and 4. Note that FIG. 3 is a cross-sectional view illustrating a structure of the film forming apparatus and FIG. 4 is a plan view thereof. The description in this embodiment mode is made with reference to both of the drawings.

In manufacturing steps of a light emitting element of this embodiment mode, the film forming apparatus shown in Embodiment Mode 3 is used. The film forming apparatus shown in Embodiment Mode 3 includes the film forming apparatus shown in Embodiment Mode 6 and a laser beam irradiation unit.

As shown in FIGS. 3 and 4, the light source 22, the optical system 23, the light introducing window 14, and the deflecting unit are provided as the laser beam irradiation unit. Here, mirrors 44 and 46 are given as an example of the deflecting unit. In other words, the light path of the laser beam which is emitted from the light source 22, shaped by the optical system 23, and introduced into the deposition chamber 10 through the light introducing window 14 is adjusted by using the mirrors 44 and 46 so that the laser beam irradiates the substrate 30. By adjusting an angle of one or both of the mirrors 44 and 46, the laser beam which is shaped into, for example, a rectangle by the optical system 23 can be scanned over a surface of the substrate 30 where a film is formed, so that the entire surface can be emitted.

As a laser oscillator which is used as the light source 22, a structure similar to that of the light source 1123 in Embodiment Mode 6 can be appropriately used.

In addition, plural equivalents of the light introducing window 14 shown in FIGS. 3 and 4 may be provided in the film forming chamber 10 so that a plurality of laser beams are emitted to the substrate.

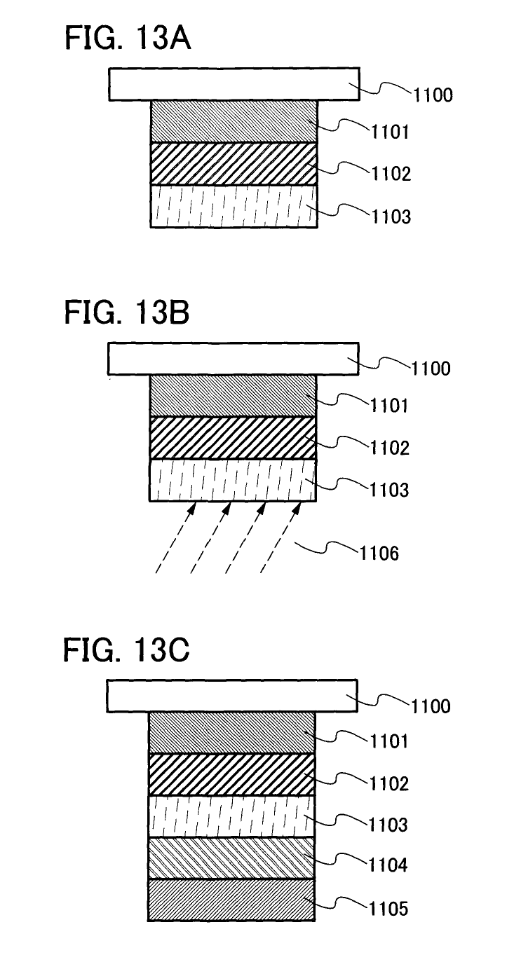

The light emitting element of this embodiment mode, is formed using the film forming apparatus shown in FIGS. 3 and 4 similarly to Embodiment Mode 6, and a vapor deposition material of the first electrode 1101 is vapor deposited on the substrate 1100, a vapor deposition material of the first insulating layer 1102 is vapor deposited on the first electrode 1101, and a vapor deposition material of the light emitting layer 1103 is vapor deposited on the first insulating layer 1102, as shown in FIG. 13A.

Subsequently, after closing the shutter 2020 of the film forming apparatus, the laser beam irradiation unit is used and the laser beam 1106 emitted from the laser oscillator irradiates any of the first electrode 1101, the first insulating layer 1102, or the light emitting layer 1103, preferably, the light emitting layer 1103, which are formed on the substrate, as shown in FIG. 13B.

Then, as shown in FIG. 13C, after stopping emission of the laser beam, the shutter 2020 of the film forming apparatus is opened and the vapor deposition materials of the second insulating layer 1104 and the second electrode 1105 are sequentially vapor deposited on the light emitting layer 1103.

Although the laser beam is shaped by the optical system 23 in FIG. 3, if necessary energy can be supplied to the substrate 30, the optical system 23 can be omitted. In addition, the lamp light source 48 may be used instead of the laser beam irradiation unit. For example, the film forming apparatus shown in FIG. 5 may be used. The film forming apparatus shown in FIG. 5 has a structure in which light emitted from the lamp light source 48 irradiates the substrate 30 in the film forming chamber 10.

Note that different from FIG. 13B, the laser beam 1106 may be emitted after sequentially forming the first electrode 1101, the first insulating layer 1102, the light emitting layer 1103, and the second insulating layer 1104 on the substrate 1100. After that, the second electrode 1105 is formed on the second insulating layer 1104.

Alternatively, the laser beam 1106 may be emitted after sequentially forming the first electrode 1101, the first insulating layer 1102, the light emitting layer 1103, the second insulating layer 1104, and the second electrode 1105 on the substrate 1100. In this case, the second electrode 1105 preferably transmits light.

Further alternatively, the laser beam irradiates the first electrode 1101, the first insulating layer 1102, the light emitting layer 1103, the second insulating layer 1104, and the second electrode 1105 from the substrate 30 side, by changing the arrangement of the deflecting unit and providing an opening to the substrate stage 12 to expose a part of the substrate 30.

By performing the foregoing steps, a light emitting element including a thin film which is dense, a thin film which has a uniform quality with reduced strain and defect, or a thin film which has favorable crystallinity can be manufactured. In addition, a light emitting element with high light emission efficiency can be manufactured.

### Embodiment Mode 8

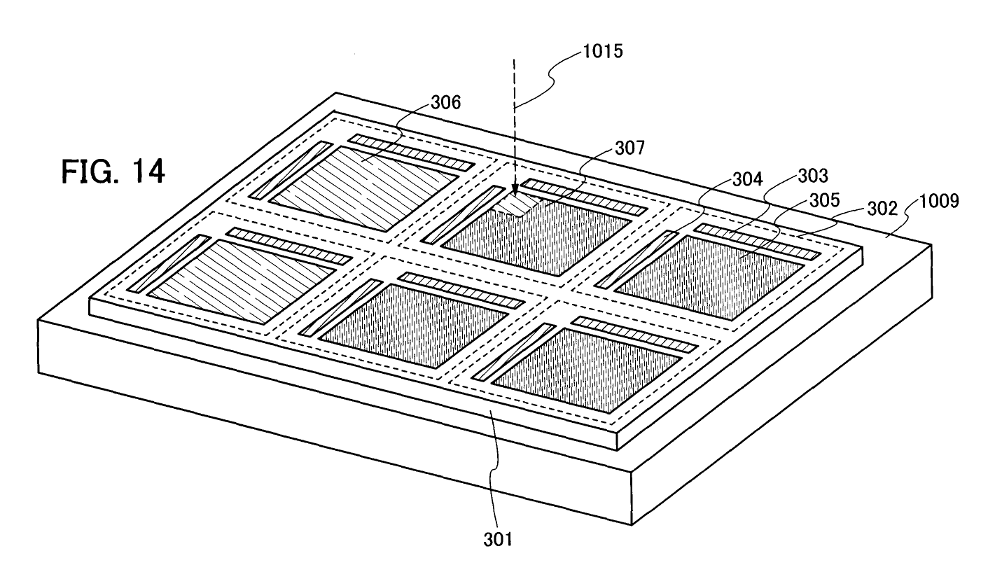

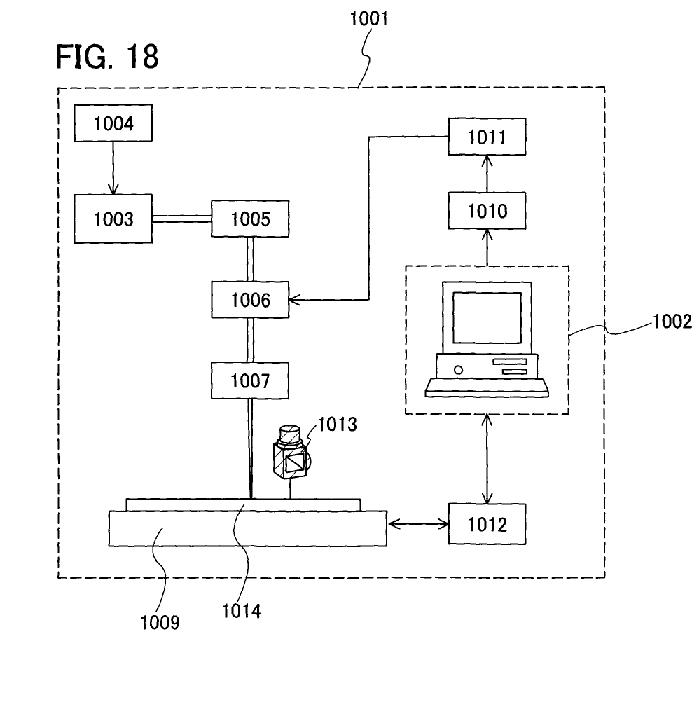

In this embodiment mode, an example in which the laser beam 1106 emitted from the laser oscillator irradiates the first electrode 1101, the first insulating layer 1102, and the light emitting layer 1103, which are formed on the substrate, is described with reference to FIGS. 14 and 18. In the example, an apparatus capable of irradiating a laser beam selectively to a predetermined region (hereinafter, referred to as a laser beam irradiation system) is used as the laser beam irradiation unit shown in Embodiment Mode 6.

A laser beam irradiation system is described with reference to FIG. 18.

A laser beam irradiation system 1001 includes a computer 1002 which conducts various controls when laser light is emitted; a laser oscillator 1003 which outputs the laser beam; a power source 1004; an optical system 1005 which attenuates the laser beam; an acousto-optic modulator 1006 which modulates intensity of the laser beam; an optical system 1007 which has a lens for reducing the size of a cross section of the laser beam, a mirror for changing a light path, and the like; a movement mechanism 1009 which has an X axis stage and a Y axis stage; a D/A converter 1010 which converts control data outputted from the computer 1002; a driver 1011 which controls the acousto-optic modulator 1006 in accordance with analog voltage outputted from the D/A converter; a driver 1012 which outputs a signal for driving the movement mechanism 1009; and an autofocusing mechanism 1013 for focusing the laser beam on an object to be irradiated (FIG. 18). As the laser oscillator 1003, the oscillator shown as the light source 1123 of the laser beam irradiation unit shown in FIG. 17 can be appropriately used.

Subsequently, an operation of the laser beam irradiation system 1001 having the foregoing structure is described. When a substrate 1014 is mounted over the movement mechanism 1009, the computer 1002 detects a position of a light emitting element to be irradiated with the laser beam by using a camera which is not shown. Then, the computer 1002 generates movement data for moving the movement mechanism 1009 based on the detected position data. Thereafter, the computer 1002 controls the amount of light outputted from the acousto-optic modulator 1006 via the driver 1011; accordingly, the laser beam emitted from the laser oscillator 1003 is attenuated by the optical system 1005 and then the amount of light thereof is controlled by using the acousto-optic modulator 1006 so that predetermined amount of light can be obtained. On the other hand, the laser beam which is emitted from the acousto-optic modulator 1006 has its light path and beam spot shape changed by the optical system 1007, is converged by the lens, then, irradiates the substrate 1014 as the laser beam 1016. At this time, the movement mechanism 1009 is controlled to move along an X direction and a Y direction in accordance with the movement data generated by the computer 1002. As a result, the laser beam is emitted to the predetermined position. Note that although the example in which the laser beam irradiation is carried out by moving the movement mechanism 1009 is described above, the laser beam may be moved along the X direction and the Y direction by adjusting the optical system 1007.

By using the foregoing laser beam irradiation system, a laser beam can be emitted selectively to the pixel portion over a substrate and a light emitting element provided in each pixel in the pixel portion.

Here, an example of emitting a laser beam selectively to the pixel portion of a substrate provided with a plurality of light emitting panels by using the laser beam irradiation system is described with reference to FIG. 14.

A substrate 301 is set on the movement mechanism 1009. A plurality of light emitting panels 302 are formed over the substrate 301. The light emitting panel includes driving circuits 303 and 304, and a pixel portion 305.

The driving circuits 303 and 304 are circuits which control driving of the light emitting element formed in the pixel portion. The driving circuits 303 and 304 include semiconductor elements such as a thin film transistor, a diode, and a resistor. Note that each of the thin film transistors formed in the driving circuits 303 and 304 preferably includes a semiconductor layer which is formed of a crystalline semiconductor film. In addition, a wiring connected to the semiconductor layer in the thin film transistor is preferably formed of a low resistance material such as aluminium or titanium. Such a thin film transistor is capable of high speed operation since it has high filed effect mobility. Further, a light emitting panel which has a driving circuit including such a thin film transistor can perform high definition display.

The light emitting element in the pixel portion 305 is formed after forming the semiconductor element in the driving circuit. Therefore, if the entire surface is irradiated with the laser beam in a process of manufacturing the light emitting element, the wiring of the thin film transistor is also irradiated with the laser beam. Since a low resistance material such as aluminium or titanium has a relatively low melting point, the wiring is melted if it is irradiated with the laser beam. As a result a problem such that yield of the light emitting panel is reduced is caused.

However, by using the laser beam irradiation system, it becomes possible to emit the laser beam selectively to the light emitting element formed in the pixel portion, and the laser beam can be emitted to a light emitting layer in the light emitting element. Accordingly, the yield can be improved.

Note that in FIG. 14, a region 306 shows a region of the pixel portion which is selectively irradiated with the laser beam and in which the light emitting element having a thin film which is dense, a thin film which has a uniform quality with reduced strain and defect, or a thin film which has favorable crystallinity is formed. On the other hand, a region 307 shows a region which is not irradiated with the laser beam.

As described above, in a process of forming the light emitting element, the laser beam is selectively emitted by using the laser beam irradiation system when irradiating any of the first electrode, the first insulating layer, the light emitting layer, the second insulating layer, and the second electrode, preferably, the light emitting layer, which are included in the light emitting element with the laser beam. Therefore, yield of the light emitting panel which has the driving circuit including the thin film transistor and the pixel portion including the light emitting element with high light emission efficiency can be improved.

### Embodiment Mode 9

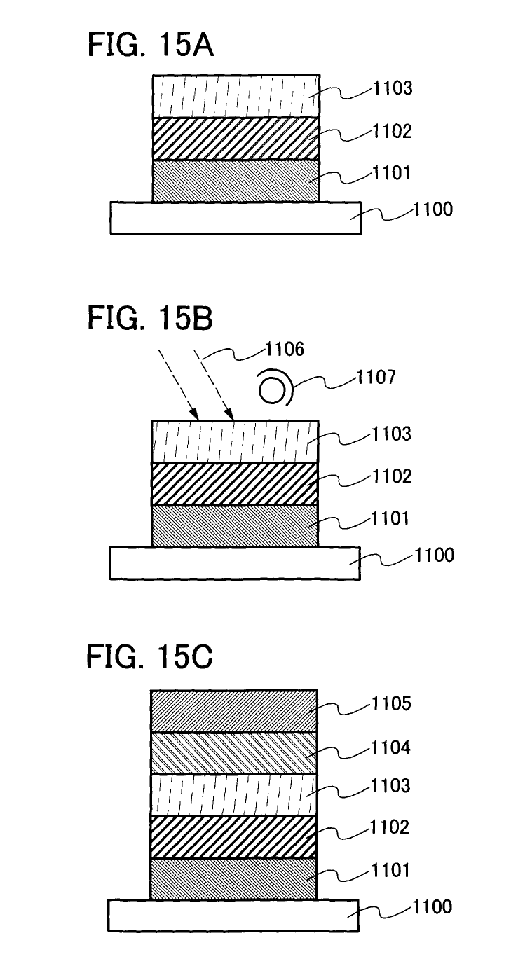

An example of emitting the laser beam 1106 from the laser oscillator, while heating with a heating unit, to any of the first electrode 1101, the first insulating layer 1102, the light emitting layer 1103, the second insulating layer 1104, and the second electrode 1105, preferably, to the light emitting layer 1103, which are formed on the substrate in Embodiment Modes 6 to 8, is described with reference to FIGS. 15A to 15C.

As shown in FIG. 15A, the first electrode 1101, the first insulating layer 1102, and the light emitting layer 1103 are sequentially formed on the substrate similarly to Embodiment Mode 6.

Then, as shown in FIG. 15B, the laser beam 1106 irradiates any of the first electrode 1101, the first insulating layer 1102, and the light emitting layer 1103, preferably, the light emitting layer 1103, which are formed on the substrate, while heating the substrate. At this time, the heating temperature is preferably in the range of 50 to 600° C. By irradiating the first electrode 1101, the first insulating layer 1102, and the light emitting layer 1103 with the laser beam while heating by using the heating unit, a thin film which is denser, a thin film which has further reduced strain and defect, or a thin film which has favorable crystallinity can be formed. Here, a lamp light source 1107 is used as the heating unit.

As the lamp light source 1107, the lamp light source 48 shown in Embodiment Mode 7 can be used.

After that, as shown in FIG. 15C, the second insulating layer 1104 and the second electrode 1105 are sequentially formed on the light emitting layer 1103 similarly to Embodiment Mode 6.

Note that the film forming apparatus shown in Embodiment Mode 7 to which a lamp is additionally provided may be used. With the use of such a film forming apparatus, the laser beam 1106 irradiates the first electrode 1101, the first insulating layer 1102, and the light emitting layer 1103, which are formed on the substrate, while heating the substrate by using the lamp light source 1107.

Note that in FIG. 15B, an example where the lamp is provided to the side on which the light emitting layer 1103 is formed, and the laser beam is emitted is shown, but the present invention is not limited thereto. For example, the lamp may be provided to the substrate side, and the laser beam may be emitted to the light emitting layer side while heating from the substrate side. Alternatively, the lamp may be provided to the light emitting layer side and the laser beam irradiates the substrate side while heating from the light emitting layer side. In this case, the substrate preferably transmits light. Further alternatively, the lamp may be provided to the substrate side while emitting the laser beam to the substrate side.

As a heating unit, a heater may be used instead of the lamp light source. Further alternatively, the substrate 1100 may be set in an electric furnace and the laser beam is emitted while heating the substrate 1100 by the electric furnace.

By performing the foregoing steps, a light emitting element including a thin film which is dense, a thin film which has a uniform quality with reduced strain and defect, or a thin film which has favorable crystallinity can be manufactured. Also, a light emitting element with high light emission efficiency can be manufactured.

### Embodiment Mode 10

In this embodiment mode, a mode of a manufacturing method of a light emitting element having a structure different from that in Embodiment Modes 6 to 9 is described with reference to FIG. 7. A manufacturing method of the light emitting element of the present invention can be applied to the light emitting element shown in FIG. 7.

The first electrode 201 is formed on the substrate 200. The first electrode 201 can be formed by a manufacturing method similar to that of the first electrode 101 in Embodiment Mode 4.

Then, the light emitting layer 202 is formed. The light emitting layer 202 can be formed using a material and a manufacturing method similar to those shown in Embodiment Modes 3 and 6. The film thickness thereof is not particularly limited, but is preferably in the range of 10 to 1000 nm.

After forming the light emitting layer 202, the light emitting layer 202 is irradiated with a laser beam as shown in Embodiment Modes 6 to 8. Alternatively, as shown in Embodiment Mode 9, the light emitting layer 202 is irradiated with a laser beam while being heated.

The insulating layer 203 is formed. The insulating layer 203 can be formed using a material and a manufacturing method similar to those of the second insulating layer 104, which are listed in Embodiment Mode 4.

The second electrode 204 is formed. The second electrode 204 can be formed using a material and a manufacturing method similar to those of the second electrode 105, which are listed in Embodiment Mode 4.

In this embodiment mode also, light emission is taken outside through the first electrode 201 or the second electrode 204, it is necessary that at least one of the first electrode 201 and the second electrode 204 transmits light.

Note that in FIG. 7, a laser beam may be emitted after sequentially forming the first electrode 201, the light emitting layer 202, and the insulating layer 203 over the substrate 200. After that, the second electrode 204 is formed over the insulating layer 203.

Alternatively, a laser beam may be emitted after sequentially forming the first electrode 201, the light emitting layer 202, the insulating layer 203, and the second electrode 204 over the substrate 200. In this case, the second electrode 204 preferably transmits light.

Although not shown, a buffer layer may be provided between the light emitting layer and the insulating layer, or between the light emitting layer and the electrode. The buffer layer has a role to facilitate injection of carriers and to suppress mixing of layers. The buffer layer is not particularly limited. For example, ZnS, ZnSe, ZnTe, CdS, SrS, BaS, or the like which is the base material in the light emitting layer; CuS; Cu₂S; or alkali halide such as LiF, CaF₂, BaF₂, or MgF₂ can be used.

In addition, although the insulating layer 203 is provided so as to be in contact with the second electrode 204 in FIG. 7, the insulating layer 203 may be provided to be in contact with the first electrode 201 by reversing the order of the insulating layer and the light emitting layer.

A light emitting element of the present invention has a light emitting layer with reduced strain and defect. Therefore, a light emitting element with high light emission efficiency and low driving voltage can be obtained. In addition, a light emitting element with reduced power consumption can be obtained since the light emission efficiency is heightened and the driving voltage is lowered.

### Embodiment Mode 11

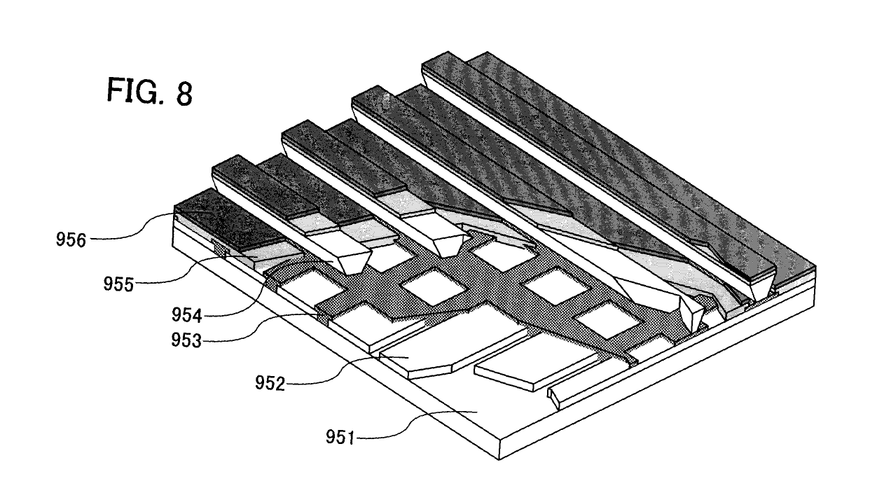

In this embodiment mode, a light emitting device which includes a light emitting element manufactured utilizing the present invention is described with reference to FIG. 8.

The light emitting device shown in this embodiment mode is a passive matrix light emitting device in which a light emitting element is driven without particularly providing an element for driving such as a transistor or the like. FIG. 8 shows a perspective view of a passive matrix light emitting device manufactured utilizing the present invention.

In FIG. 8, a layer containing a light emitting material 955 is provided between an electrode 952 and an electrode 956, over a substrate 951. The layer containing a light emitting material 955 includes the light emitting layer shown in Embodiment Mode 3.

An edge portion of the electrode 952 is covered with an insulating layer 953. A partition layer 954 is provided over the insulating layer 953. The side walls of the partition layer 954 slope so that the distance between one side wall and the other side wall becomes narrow toward a substrate surface. In other words, a cross section of the partition layer 954 in the direction of a narrow side is trapezoidal, and the bottom side (a side facing the same direction as a plane direction of the insulating layer 953 and is in contact with the insulating layer 953) is shorter than the upper layer (a side facing the same direction as the plane direction of the insulating layer 953 and not is in contact with the insulating layer 953). By providing the partition layer 945 in such a manner, a defect of the light emitting element due to static electricity or the like can be prevented. The passive matrix light emitting device can also be driven with low power consumption when a light emitting element which is manufactured utilizing the present invention and is operated with low driving voltage is included.

In addition, the light emitting device shown in this embodiment mode does not require a driving circuit which withstands high voltage; therefore, manufacturing cost of the light emitting device can be reduced. Further, it is possible to reduce the weight of the light emitting device and the size of a driving circuit portion.

Note that the light emitting device shown in this embodiment mode can employ the structure of the light emitting element shown in Embodiment Mode 4, or the structure of the light emitting element shown in Embodiment Mode 5. That is, the light emitting element manufactured according to Embodiment Modes 1 to 10 can be employed. In addition, it is possible to manufacture a light emitting device which operates by DC driving and to manufacture a light emitting device which operates by AC driving.

### Embodiment Mode 12

In this embodiment mode, a light emitting device which includes a light emitting element manufactured utilizing the present invention is described.

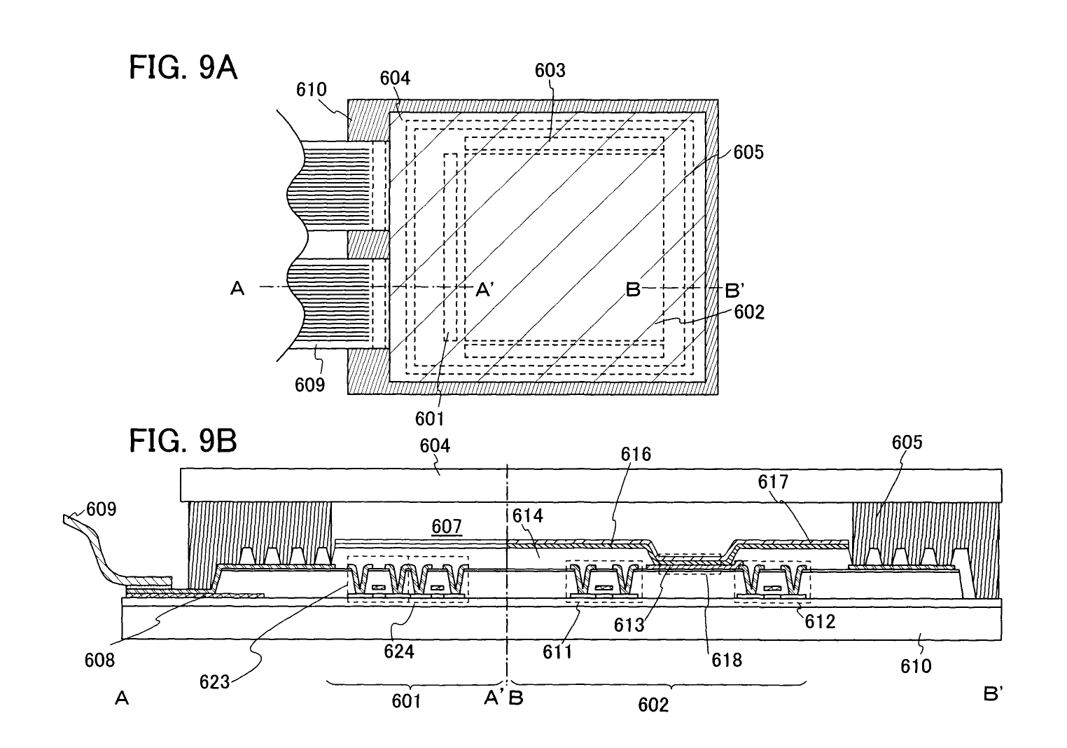

In this embodiment mode, an active matrix light emitting device in which driving of a light emitting element is controlled by a transistor is described. In this embodiment mode, a light emitting device including a pixel portion which has a light emitting element manufactured utilizing the present invention is described with reference to FIGS. 9A and 9B. FIG. 9A is a top view showing the light emitting device and FIG. 9B is a cross-sectional view of FIG. 9A taken along lines A-A′ and B-B′. Reference numeral 601 denotes a driving circuit portion (a source side driving circuit); 602, a pixel portion; 603, a driving circuit portion (a gate side driving circuit); which are indicated by dashed lines. Reference numeral 604 denotes a sealing substrate and 605 denotes a sealant. Reference numeral 607 denotes a space surrounded by the sealant 605.

Note that a lead wiring 608 is a wiring for transferring signals to be inputted to the source side driving circuit 601 and the gate side driving circuit 603. The lead wiring 608 receives a video signal, a clock signal, a start signal, a reset signal, and the like from an FPC (flexible printed circuit) 609 which serves as an external input terminal. Although only the FPC is shown here, this FPC may be provided with a printed wiring board (PWB). A light emitting device in this specification refers to not only a main body of a light emitting display device, but also a light emitting display device provided with an FPC or a PWB.

A cross-sectional structure is described with reference to FIG. 9B. The driving circuit portions and the pixel portion are formed over an element substrate 610. Here, the source side driving circuit 601 which is the driving circuit portion and one pixel in the pixel portion 602 are shown.

Note that as the source side driving circuit 601, a CMOS circuit in which an n-channel TFT 623 and a p-channel TFT 624 are combined is formed. The driving circuit may be formed using a known CMOS circuit, PMOS circuit, or NMOS circuit. Although a driver integration type in which a driving circuit is formed over the substrate is described in this embodiment mode, it is not necessarily required. The driving circuit can be formed not over the substrate, but outside the substrate. Note that a structure of a TFF is not particularly limited. Either a staggered TFT or an inversed staggered TFT may be employed. Also, the crystallinity of a semiconductor film used in the TFT is not particularly limited. Either an amorphous semiconductor film or a crystalline semiconductor film may be used. In addition, a semiconductor material is not particularly limited. Either an inorganic compound or an organic compound may be used.

The pixel portion 602 includes a plurality of pixels each having a switching TFT 611, a current controlling TFr 612, and a first electrode 613 electrically connected to a drain of the current controlling TFT 612. Note that an insulator 614 is formed to cover an edge portion of the first electrode 613. Here, the insulator 614 is formed using a positive photosensitive acrylic resin film.

The insulator 614 is formed to have a curved surface at an upper end or a lower end so as to make the coverage favorable. When positive photosensitive acrylic is used as a material of the insulator 614, the insulator 614 is preferably formed to have a curved surface with a curvature radius (0.2 to 3 μm) only at an upper end. Either a negative type which becomes insoluble in an etchant by light irradiation or a positive type which becomes soluble in an etchant by light irradiation can be used as the insulator 614.

Over the first electrode 613, a layer containing a light emitting material 616 and a second electrode 617 are formed. At least one of the first electrode 613 and the second electrode 617 transmits light, so that light emitted from the layer containing a light emitting material 616 can be taken outside.

The layer containing a light emitting material 616 has the light emitting layer shown in Embodiment Mode 3.

The light emitting element 618 is formed by appropriately using Embodiment Modes 1 to 10.

Various methods can be used as a forming method of the first electrode 613, the layer containing a light emitting material 616, and the second electrode 617. In specific, a vacuum vapor deposition method such as a resistance heating vapor deposition method or an electron beam vapor deposition (EB vapor deposition) method, a physical vapor deposition (PVD) method such as a sputtering method, a chemical vapor deposition (CVD) method such as a metal organic CVD method or a low-pressure hydride transport CVD method, an atomic layer epitaxy (ALE) method, or the like can be used. Alternatively, an ink jet method, a spin coating method, or the like can be used. In addition, a film forming method may differ between the electrodes and the layers. Note that the light emitting layer included in the layer containing a light emitting material 616 may be formed by the film forming apparatus and the film forming method shown in Embodiment Modes 1 and 2.

The sealing substrate 604 and the element substrate 610 are attached to each other with the sealant 605. Accordingly, a structure in which the light emitting element 618 is located in the space 607 surrounded by the element substrate 610, the sealing substrate 604, and the sealant 605 is formed. Note that the space 607 is filled with a filler. There is a case in which the space 607 is filled with the sealant 605, as well as a case in which the space 607 is filled with an inert gas (such as nitrogen or argon).

Note that an epoxy-based resin is preferably used as the sealant 605. The material desirably allows as little moisture and oxygen as possible to penetrate. As the sealing substrate 604, a plastic substrate formed of FRP (Fiberglass-Reinforced Plastics), PVF (polyvinyl fluoride), Mylar, polyester, acrylic, or the like can be used, in addition to a glass substrate or a quartz substrate.

In the foregoing manner, a light emitting device including a light emitting element manufactured utilizing the present invention can be obtained.

The light emitting device shown in this embodiment mode includes the light emitting element shown in Embodiment Mode 4 or 5. The light emitting element shown in Embodiment Mode 4 or 5 can operate with low driving voltage and realize high light emission efficiency. Therefore, a light emitting device with reduced power consumption can be obtained.

The light emitting device shown in this embodiment mode includes the light emitting element manufactured by any of the manufacturing methods shown in Embodiment Modes 1 to 10. The light emitting element formed by the manufacturing method shown in Embodiment Modes 1 to 10 can operate with low driving voltage and realize high light emission efficiency. Therefore, a light emitting device with reduced power consumption can be obtained.

In addition, the light emitting device shown in this embodiment mode does not require a driving circuit which withstands high voltage; therefore, manufacturing cost of the light emitting device can be reduced. Further, it is possible to reduce the weight of the light emitting device and the size of a driving circuit portion.

### Embodiment Mode 13

In this embodiment mode, an electronic appliance which includes the light emitting device shown in Embodiment Mode 11 or 12 in its part is described. The electronic appliance shown in this embodiment mode has the light emitting element shown in Embodiment Mode 4 or 5. That is, the electronic appliance shown in this embodiment has the light emitting element formed by the manufacturing method described in Embodiment Modes 1 to 10. Since a light emitting element whose driving voltage is reduced is included, an electronic appliance with reduced power consumption can be provided.

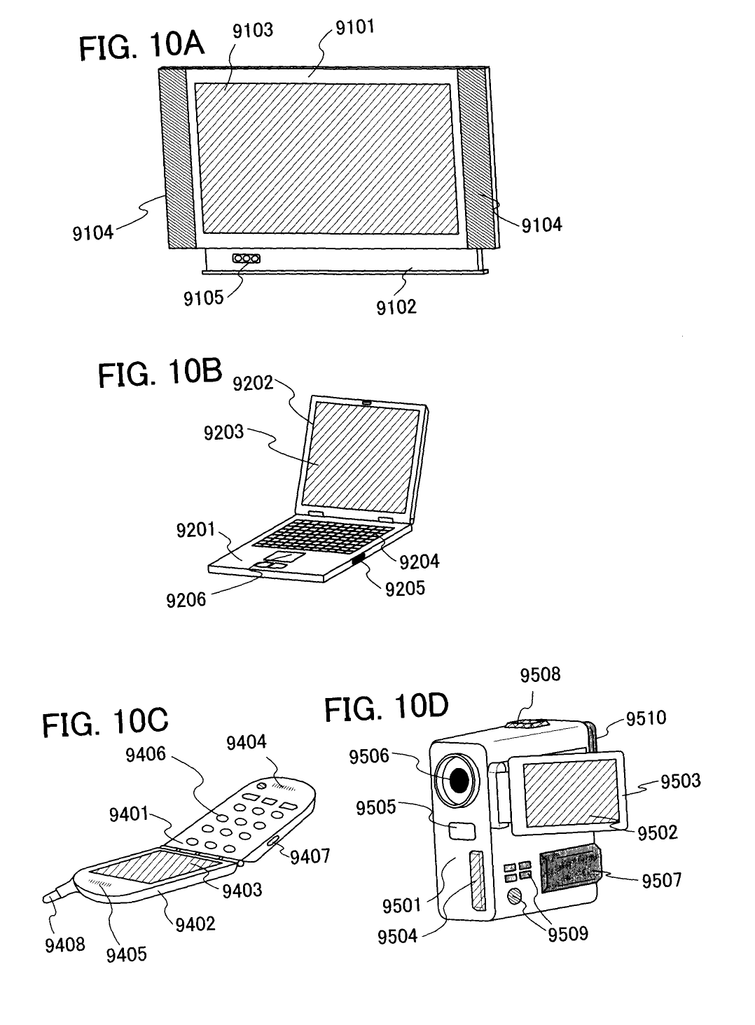

As electronic appliances which are manufactured utilizing the present invention, a video camera, a digital camera, a goggle type display, a navigation system, an audio reproducing device (car audio, an audio component, or the like), a computer, a game machine, a portable information terminal (a mobile computer, a mobile phone, a portable game machine, an electronic book, or the like), an image reproducing device provided with a recording medium (specifically, a device which reproduces a recording medium such as a digital versatile disc (DVD) and which is provided with a display device for displaying the image), and the like can be given. Specific examples of these electronic appliances are shown in FIGS. 10A to 10D.

FIG. 10A shows a television apparatus utilizing the present invention, which includes a chassis 9101, a support 9102, a display portion 9103, a speaker portion 9104, a video input terminal 9105, and the like. In the television apparatus, the display portion 9103 has light emitting elements which are similar to those described in Embodiment Modes 4 and 5, arranged in matrix. The light emitting element has high light emission efficiency and low driving voltage. In addition, short circuit due to impact from outside, or the like can be prevented. The display portion 9103 which includes the light emitting elements has similar features. Therefore, in the television apparatus, image quality is hardly deteriorated and low power consumption can be achieved. With such features, a deterioration compensation circuit and a power source circuit can be significantly reduced or downsized, whereby reduction in size and weight of the chassis 9101 and the support 9102 are possible. Since the television apparatus utilizing the present invention can achieve low power consumption, high image quality and reduction in size and weight, products suitable for living environment can be provided.

FIG. 10B shows a computer utilizing the present invention, which includes a main body 9201, a chassis 9202, a display portion 9203, a keyboard 9204, an external connection port 9205, a pointing mouse 9206, and the like. In the computer, the display portion 9203 has light emitting elements which are similar to those described in Embodiment Modes 4 and 5, arranged in matrix. The light emitting element has high light emission efficiency and low driving voltage. In addition, short circuit due to impact from outside, or the like can be prevented. The display portion 9203 which includes the light emitting elements has similar features. Therefore, in the computer, image quality is hardly deteriorated and low power consumption can be achieved. With such features, a deterioration compensation circuit and a power source circuit can be significantly reduced or downsized, whereby reduction in size and weight of the main body 9201 and the chassis 9202 are possible. Since the computer utilizing the present invention can achieve low power consumption, high image quality and reduction in size and weight, products suitable for environment can be provided. In addition, a portable computer with a display portion which is resistant to impact from outside when being carried can be provided.

FIG. 10C shows a mobile phone utilizing the present invention, which includes a main body 9401, a chassis 9402, a display portion 9403, an audio input portion 9404, an audio output portion 9405, an operation key 9406, an external connection port 9407, an antenna 9408, and the like. In the mobile phone, the display portion 9403 has light emitting elements which are similar to those described in Embodiment Modes 4 and 5, arranged in matrix. The light emitting element has high light emission efficiency and low driving voltage. In addition, short circuit due to impact from outside, or the like can be prevented. The display portion 9403 which includes the light emitting elements has similar features. Therefore, in the mobile phone, image quality is hardly deteriorated and low power consumption can be achieved. With such features, a deterioration compensation circuit and a power source circuit can be significantly reduced or downsized, whereby reduction in size and weight of the main body 9401 and the chassis 9402 are possible. Since the mobile phone utilizing the present invention can achieve low power consumption, high image quality and reduction in size and weight, products suitable for being carried can be provided. In addition, a product with a display portion which is resistant to impact from outside when being carried can be provided.

FIG. 10D shows a camera which includes a main body 9501, a display portion 9502, a chassis 9503, an external connection port 9504, a remote control receiving portion 9505, an image receiving portion 9506, a battery 9507, an audio input portion 9508, an operation key 9509, an eye piece portion 9510, and the like. In this camera, the display portion 9502 has light emitting elements which are similar to those described in Embodiment Modes 4 and 5, arranged in matrix. The light emitting element has high light emission efficiency and high driving voltage. In addition, short circuit thereof due to impact from outside, or the like can be prevented. The display portion 9502 which includes the light emitting elements has similar features. Therefore, in the camera, image quality is hardly deteriorated and low power consumption can be achieved. With such features, a deterioration compensation circuit and a power source circuit can be significantly reduced or downsized in the camera, whereby reduction in size and weight of the main body 9501 are possible. Since the camera utilizing the present invention can achieve low power consumption, high image quality and reduction in size and weight, products suitable for being carried can be provided. In addition, a product with a display portion which is resistant to impact from outside when being carried can be provided.

As described above, a light emitting device manufactured utilizing the present invention can be applied widely and used in various fields of electronic appliances. By applying the present invention, an electronic appliance having a display portion with low power consumption and high reliability can be manufactured.

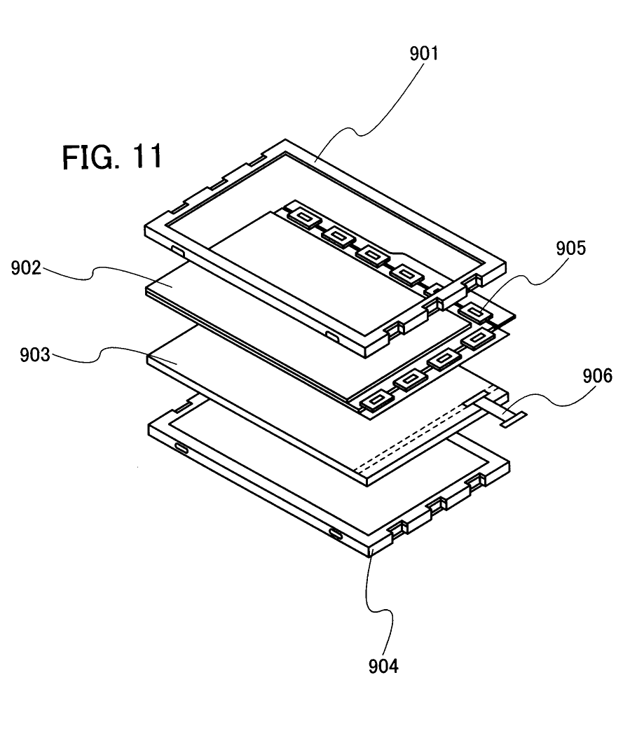

In addition, a light emitting device to which the present invention is applied has a light emitting element with high light emission efficiency, and can be used as a lighting device. A mode in which a light emitting element to which the present invention is applied is used as a lighting device is described with reference to FIG. 11.

FIG. 11 shows an example of a liquid crystal display device which uses a light emitting device to which the present invention is applied, as a backlight. A liquid crystal display device shown in FIG. 11 includes a chassis 901, a liquid crystal layer 902, a back light 903 and a chassis 904. The liquid crystal layer 902 is connected to a driver IC 905. In addition, a light emitting device of the present invention is used in the back light 903 and current is supplied thereto through a terminal 906.

By using a light emitting device to which the present invention is applied as a back light of a liquid crystal display device, a back light with reduced power consumption can be obtained. In addition, a light emitting device to which the present invention is applied is a lighting device which performs surface light emission, and the area of which can be enlarged; therefore, a liquid crystal display device can be also enlarged. Further, since the light emitting device has a thin shape and reduced power consumption, the display device can also have reduced thickness and power consumption.

This application is based on Japanese Patent Application serial no. 2006-034510 filed in Japan Patent Office on Feb. 10, in 2006 and on Japanese Patent Application serial no. 2006-034514 filed in Japan Patent Office on Feb. 10, in 2006, the entire contents of which are hereby incorporated by reference.

What is claimed is:

1. A film forming apparatus comprising:
a film forming chamber including an evaporation source filled with a vapor deposition material, and a substrate holding unit holding a substrate so that at least a part of a surface of the substrate is exposed; and
a laser beam irradiation unit emitting a laser beam,
wherein the laser beam irradiation unit is provided so as to irradiate the surface of the substrate which is exposed with the laser beam.

2. The film forming apparatus according to claim 1,
wherein the laser beam irradiation unit is provided so that the surface of the substrate which is exposed is irradiated with the laser beam approximately perpendicularly.

3. The film forming apparatus according to claim 1,
wherein the laser beam irradiation unit is provided so that the laser beam is emitted between the substrate and the evaporation source and so that the laser beam is emitted approximately parallel to the surface of the substrate which is exposed.

4. The film forming apparatus according to claim 1,
wherein the film forming chamber has a light introducing window, and
wherein the laser beam irradiation unit is provided so that the laser beam is introduced into the film forming chamber through the light introducing window.

5. The film forming apparatus according to claim 1, wherein a wavelength of the laser beam is absorbed by the vapor deposition material.

6. The film forming apparatus according to claim 1,
wherein a laser oscillator selected from a group consisting of an Ar laser, a Kr laser, a carbon dioxide laser, a YAG laser, a YLF laser, a YAlO₃ laser, a GdVO₄ laser, a KGW laser, a KYW laser, an alexandrite laser, a Ti: sapphire laser, a Y₂O₃ laser, a YVO₄ laser, a helium-cadmium laser, a KrF excimer laser, an ArF excimer laser, an XeCl excimer laser, and an XeF excimer laser is used as a laser light source of the laser beam irradiation unit.

7. The film forming apparatus according to claim 1, wherein a light receiving plate absorbing the laser beam is provided.

8. The film forming apparatus according to claim 1, wherein a plurality of evaporation sources are provided.

9. The film forming apparatus according to claim 1, wherein an electron beam emitting unit irradiating the vapor deposition material filled in the evaporation source with an electron beam is provided.

10. The film forming apparatus according to claim 1, wherein a heating unit heating the vapor deposition material filled in the evaporation source is provided.

11. A manufacturing method of a light emitting element, comprising:
forming a first electrode over a substrate;
forming a light emitting layer over the first electrode, said light emitting layer is formed by a method comprising:
fixing the substrate to a substrate holding unit so that at least a part of a surface of the substrate is exposed;
evaporating a vapor deposition material from an evaporation source filled with the vapor deposition material;
irradiating the vapor deposition material which is evaporated with a laser beam; and
depositing the vapor deposition material over the first electrode, and forming a second electrode,
wherein the vapor deposition material comprises at least one selected from the group consisting of zinc sulfide, cadmium sulfide, calcium sulfide, yttrium sulfide, gallium sulfide, strontium sulfide, barium sulfide, zinc oxide, yttrium oxide, aluminum nitride, gallium nitride, indium nitride, zinc selenide, zinc telluride, calcium gallium sulfide, strontium gallium sulfide, and barium gallium sulfide.

12. The method according to claim 11
wherein the vapor deposition material which is evaporated is irradiated with the laser beam by irradiating the surface of the substrate which is exposed with the laser beam approximately perpendicularly.

13. The method accoding to claim 11,
wherein the vapor deposition material which is evaporated is irradiated with the laser beam, by emitting the laser beam between the substrate and the evaporation source and approximately parallel to the surface of the substrate which is exposed.

14. The method according to claim 11, wherein a wavelength of the laser beam is absorbed by the vapor deposition material.

15. A manufacturing method of a light emitting element, comprising:
forming a first electrode over a substrate;
forming a light emitting layer over the first electrode, said light emitting layer is formed by a method comprising:
fixing the substrate to a substrate holding unit so that at least a part of a surface of the substrate is exposed;
evaporating a vapor deposition material from an evaporation source filled with the vapor deposition material;
irradiating the vapor deposition material which is evaporated with lamp light; and
depositing the vapor deposition material over the first electrode, and forming a second electrode,
wherein the vapor deposition material comprises at least one selected from the group consisting of zinc sulfide, cadmium sulfide, calcium sulfide, yttrium sulfide, gallium sulfide, strontium sulfide, barium sulfide, zinc oxide, yttrium oxide, aluminum nitride, gallium nitride, indium nitride, zinc selenide, zinc telluride, calcium gallium sulfide, strontium gallium sulfide, and barium gallium sulfide.

16. The method according to claim 15, wherein a wavelength of the lamp light is absorbed by the vapor deposition material.

17. The method according to claim 11, wherein the vapor deposition material is evaporated by irradiating the vapor deposition material filled in the evaporation source with an electron beam.

18. The method according to claim 11, wherein the vapor deposition material is evaporated by heating the vapor deposition material filled in the evaporation source.

19. The method according to claim 15, wherein the vapor deposition material is evaporated by irradiating the vapor deposition material filled in the evaporation sourcewith an electron beam.

20. The method according to claim 15, wherein the vapor deposition material is evaporated by heating the vapor deposition material filled in the evaporation source.

21. The method according to claim 11 further comprising:
forming a first insulating layer after forming the first electrode.

22. The method according to claim 11 further comprising:
forming a second insulating layer after forming the light emitting layer.

23. The method according to claim 15 further comprising:
forming a first insulating layer after forming the first electrode.

24. The method according to claim 15 further comprising:
forming a second insulating layer after forming the light emitting layer.

25. A manufacturing method of a light emitting element comprising:
forming a first electrode over a substrate;
forming a vapor deposition film over the first electrode;
irradiating the vapor deposition film with a laser beam while heating the vapor deposition film; and
forming a second electrode on the vapor deposition film.

26. The manufacturing method of the light emitting element according to claim 25 further comprising:
irradiating the second electrode with a second laser beam after forming the second electrode.

27. The manufacturing method of the light emitting element, according to claim 25, wherein the vapor deposition film is irradiated with the laser beam from a surface side of the vapor deposition film.

28. The manufacturing method of the light emitting element, according to claim 25, wherein the vapor deposition film is irradiated with the laser beam from a substrate side.

29. The manufacturing method of the light emitting element, according to claim 25, wherein the vapor deposition film is heated at a temperature in a range of 50 to 600° C. during the laser irradiation.

30. A manufacturing method of a light emitting element, comprising:
forming a first electrode over a substrate;
forming a vapor deposition film over the first electrode;
forming a second electrode over the vapor deposition film; and
irradiating the second electrode with a laser beam.

31. The manufacturing method of the light emitting element according to claim 25, wherein the vapor deposition film contains a light emitting material.

32. The manufacturing method of the light emitting element according to claim 30, wherein the vapor deposition film contains a light emitting material.

33. A manufacturing method of a light emitting element comprising:
forming a first electrode over a substrate;
forming an insulating layer over the first electrode;
forming a light emitting layer over the insulating layer by a vapor deposition method;
irradiating the light emitting layer with a laser beam; and
forming a second electrode over the light emitting layer.

34. A manufacturing method of a light emitting element, comprising:
forming a first electrode over a substrate;
forming a light emitting layer over the first electrode by a vapor deposition method;
irradiating the light emitting layer with a laser beam;
forming an insulating layer over the light emitting layer; and
forming a second electrode over the insulating layer.

35. The manufacturing method of a light emitting element according to claim 33 further comprising:
forming a second insulating layer over the light emitting layer after irradiating the light emitting layer with the laser beam and before forming the second electrode.

36. The manufacturing method of the light emitting element, according to claim 33, wherein the light emitting layer is irradiated with the laser beam while the light emitting layer is heated.

37. The manufacturing method of the light emitting element, according to claim 33, wherein the second electrode is irradiated with a second laser beam after forming the second electrode.

38. The manufacturing method of the light emitting element, according to claim 33, wherein the light emitting layer is irradiated with the laser beam from a surface side of the light emitting layer.

39. The manufacturing method of the light emitting element, according to claim 33, wherein the light emitting layer is irradiated with the laser beam from a substrate side.

40. The manufacturing method of the light emitting element, according to claim 34, wherein the light emitting layer is irradiated with the laser beam while the light emitting layer is heated.

41. The manufacturing method of the light emitting element, according to claim 34, wherein the second electrode is irradiated with a second laser beam after forming the second electrode.

42. The manufacturing method of the light emitting element, according to claim 34, wherein the light emitting layer is irradiated with the laser beam from a surface side of the light emitting layer.

43. The manufacturing method of the light emitting element, according to claim 34, wherein the light emitting layer is irradiated with the laser beam from a substrate side.

44. The manufacturing method of the light emitting element, according to claim 33, wherein the light emitting layer comprises at least one selected from the group consisting of zinc sulfide, cadmium sulfide, calcium sulfide, yttrium sulfide, gallium sulfide, strontium sulfide, barium sulfide, zinc oxide, yttrium oxide, aluminum nitride, gallium nitride, indium nitride, zinc selenide, zinc telluride, calcium gallium sulfide, strontium gallium sulfide, and barium gallium sulfide.

45. The manufacturing method of the light emitting element, according to claim 33, wherein the insulating layer comprises at least one selected from the group consisting of zinc sulfide, cadmium sulfide, calcium sulfide, yttrium sulfide, gallium sulfide, strontium sulfide, barium sulfide, zinc oxide, yttrium oxide, aluminum nitride, gallium nitride, indium nitride, zinc selenide, zinc telluride, calcium gallium sulfide, strontium gallium sulfide, and barium gallium sulfide.

46. The manufacturing method of the light emitting element, according to claim 34, wherein the light emitting layer comprises at least one selected from the group consisting of zinc sulfide, cadmium sulfide, calcium sulfide, yttrium sulfide, gallium sulfide, strontium sulfide, barium sulfide, zinc oxide, yttrium oxide, aluminum nitride, gallium nitride, indium nitride, zinc selenide, zinc telluride, calcium gallium sulfide, strontium gallium sulfide, and barium gallium sulfide.

47. The manufacturing method of the light emitting element, according to claim 34, wherein the insulating layer comprises at least one selected from the group consisting of zinc sulfide, cadmium sulfide, calcium sulfide, yttrium sulfide, gallium sulfide, strontium sulfide, barium sulfide, zinc oxide, yttrium oxide, aluminum nitride, gallium nitride, indium nitride, zinc selenide, zinc telluride, calcium gallium sulfide, strontium gallium sulfide, and barium gallium sulfide.
